(19) United States
(12) Patent Application Publication
(10) Pub. No.: US 2026/0011973 A1
(43) Pub. Date: Jan. 8, 2026

(54) OPTICAL MODULE AND ELECTRONIC DEVICE INCLUDING SAME

(71) Applicant: SAMSUNG ELECTRONICS CO., LTD., Suwon-si (KR)

(72) Inventors: Byeonghoon PARK, Suwon-si (KR); Yeongeun KIM, Suwon-si (KR); Youngseop BAE, Suwon-si (KR); Junghyun LEE, Suwon-si (KR)

(73) Assignee: SAMSUNG ELECTRONICS CO., LTD., Suwon-si (KR)

(21) Appl. No.: 19/048,194

(22) Filed: Feb. 7, 2025

Related U.S. Application Data
(63) Continuation of application No. PCT/KR2025/099242, filed on Feb. 4, 2025.

(30) Foreign Application Priority Data
Jul. 4, 2024 (KR) 10-2024-0088046
Oct. 7, 2024 (KR) 10-2024-0135940

(51) Int. Cl. H01S 5/02208; G01S 7/481; H01S 5/02253; H01S 5/0239; H04M 1/02

(52) U.S. Cl. CPC H01S 5/02208; G01S 7/4813; G01S 7/4814; H01S 5/02253; H01S 5/0239; H04M 1/026

(57) ABSTRACT

An optical module includes a first substrate, a light-emitting element assembly on the first substrate and configured to emit light in a predetermined wavelength band, a light-receiving element on the first substrate and adjacent to one side of the light-emitting element assembly, the light-receiving element including a first detection area configured to receive first light that is emitted by the light-emitting element assembly and then reflected by a subject, and a first casing on the first substrate, the first casing including a first accommodation space, a second accommodating space accommodating the first detection area, a guide structure, and a partition extending from an inner surface between the guide structure and the first accommodation space and facing the light-receiving element, where the light-receiving element further includes a second detection area adjacent to one side of the first detection area and at least partially inside the guide structure

### CROSS-REFERENCE TO RELATED APPLICATIONS

This application is a continuation of International Application No. PCT/KR2025/099242, filed on Feb. 4, 2025, in the Korean Intellectual Property Receiving Office, which is based on and claims priority to Korean Patent Application No. 10-2024-0088046, filed on Jul. 4, 2024, in the Korean Intellectual Property Office, and Korean Patent Application No. 10-2024-0135940 filed on Oct. 7, 2024, in the Korean Intellectual Property Office, the disclosures of which are incorporated by reference herein in their entireties.

### BACKGROUND

### 1. Field

The disclosure relates to an optical module and an electronic device including the same.

### 2. Description of Related Art

As electronic, information, and communication technologies have developed, various functions have come to be integrated into a single electronic device. For example, a smartphone may include functions of a sound playback device, an imaging device, or a digital diary, in addition to a communication function, and more functions may be implemented in the smartphone through additional installation of applications. As various functions are implemented in a single electronic device, specialized electronic devices such as an electronic notebook, a multimedia player, and a small digital camera are being replaced by a multifunctional electronic device such as a smartphone.

As various functions are implemented in a single electronic device and are carried and used on a daily basis, a user may demand convenient usability, portability, and high performance (e.g., fast information processing or high-quality images and sound) of the electronic device. For example, an electronic device may provide higher quality images and sound by including an advanced display and speaker, and the performance of programs or integrated circuit chips for processing image or sound signals is improving.

In a miniaturized electronic device such as a smartphone, it may be difficult to improve the quality of captured images or videos. For example, a camera provided in an electronic device may improve the quality of captured images or videos by including a high-resolution image sensor, but there may be limitations in placing a lens (or lens assembly) that simultaneously satisfies telephoto performance, wide-angle performance, or close-up performance on a miniaturized electronic device. By arranging multiple cameras (e.g., a telephoto camera, a wide-angle camera, a close-up camera, or a portrait camera) in a single electronic device, it may be possible to implement a miniaturized electronic device while improving the quality of captured images or videos. For example, when implementing a single camera with good telephoto characteristics, wide-angle characteristics, and/or close-up characteristics, the number of lenses increases and a mechanism for adjusting the relative positions of the lenses is required, which may make it difficult to install in a miniaturized electronic device. On the other hand, when combining multiple cameras with different angles of view, it may be easy to install in a miniaturized electronic device while improving the quality of captured images.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Provided is an optical module and/or an electronic device including the same in which deviation of detection information for a subject distance according to an operating environment may be suppressed.

Additional aspects will be set forth in part in the description which follows and, in part, will be apparent from the description, or may be learned by practice of the presented embodiments.

According to an aspect of the disclosure, an optical module may include a first substrate, a light-emitting element assembly on the first substrate and configured to emit light in a predetermined wavelength band, a light-receiving element on the first substrate and adjacent to one side of the light-emitting element assembly, the light-receiving element including a first detection area configured to receive first light that is emitted by the light-emitting element assembly and then reflected by a subject, and a first casing on the first substrate, the first casing including a first accommodation space, a second accommodating space accommodating the first detection area, a guide structure between the first accommodation space and the second accommodation space, and a partition extending from an inner surface between the guide structure and the first accommodation space and facing the light-receiving element, where the light-receiving element further includes a second detection area adjacent to one side of the first detection area and at least partially inside the guide structure, and the second detection area is configured to receive second light that is a portion of the light emitted by the light-emitting element assembly and that is guided by the guide structure.

The light-emitting element assembly may include a second substrate including a ceramic material, a driving circuit on the second substrate, and a light-emitting element controlled by the driving circuit and configured to emit the light in the predetermined wavelength band.

The light-emitting element assembly may include a second casing on the second substrate and accommodating at least the light-emitting element, and a first guide hole on the second casing and aligned with the guide structure of the first casing, where the first guide hole is configured to guide the second light into an interior of the guide structure.

The optical module may include at least one reflective member in an interior space of the second casing or the interior of the guide structure.

The optical module may include another partition inside the first casing and between the guide structure and the light-emitting element assembly, and a second guide hole at least partially surrounded by the other partition and the first substrate, where the first guide hole is aligned with the second guide hole.

The light-emitting element assembly may include a diffractive optical element and a collimator, and where the diffractive optical element and the collimator are configured to guide or align at least a portion of the light emitted from the light-emitting element in a predetermined direction.

The light-emitting element may include a vertical cavity surface emitting laser.

The optical module may include a lens assembly on the first casing and configured to guide or focus the first light to the first detection area.

The light-emitting element assembly may be accommodated in the first accommodation space.

The partition may be configured to suppress or block the first light from being incident on the second detection area.

The partition may be configured to suppress or block the second light from being incident on the first detection area.

The partition may be arranged to form a closed curve trajectory corresponding to an edge of the first detection area.

At least a portion of an inner surface of the guide structure may be inclined with respect to the first substrate.

According to an aspect of the disclosure, an electronic device may include a housing, an optical module in the housing, the optical module configured to emit light of a predetermined wavelength band and receive first light reflected by a subject, at least one processor, and memory configured to store instructions that, when executed by the at least one processor, cause the electronic device to determine distance information to the subject based on at least the first light, where the optical module may include a first substrate, a light-emitting element assembly on the first substrate and configured to emit the light of the predetermined wavelength band, a light-receiving element on the first substrate and adjacent to one side of the light-emitting element assembly, the light-receiving element including a first detection area configured to receive the first light, and a first casing on the first substrate, the first casing including a first accommodation space accommodating the light-emitting element assembly, a second accommodation space accommodating the first detection area, and a guide structure between the first accommodation space and the second accommodation space, where the light-receiving element further includes a second detection area adjacent to one side of the first detection area and at least partially inside the guide structure, and the second detection area is configured to receive second light that is a portion of the light emitted by the light-emitting element assembly and that is guided by the guide structure.

The light-emitting element assembly may include a second substrate including a ceramic material, a driving circuit on the second substrate, a light-emitting element controlled by the driving circuit and configured to emit the light in the predetermined wavelength band, a second casing on the second substrate and accommodating at least the light-emitting element, and a first guide hole on the second casing and aligned with the guide structure, and where the first guide hole is configured to guide the second light into an interior of the guide structure.

The light-emitting element assembly may include at least one reflective member in an interior space of the second casing or the interior of the guide structure.

The light-emitting element assembly may include a diffractive optical element, and a collimator, and the diffractive optical element and the collimator may be configured to guide or align at least a portion of the light emitted from the light-emitting element in a predetermined direction.

The light-emitting element may include a vertical cavity surface emitting laser.

The light-emitting element assembly may include a partition extending from an inner surface of the first casing between the guide structure and the second accommodation space and arranged to face the light-receiving element.

The partition may be configured to suppress or block the first light from being incident on the second detection area, and suppress or block the second light from being incident on the first detection area.

According to an aspect of the disclosure, an optical module may include a light-emitting element assembly including a light-emitting element configured to emit first light, a light-receiving element adjacent to the light-emitting element assembly, the light-receiving element including a first detection area and a second detection area adjacent to the first detection area, a first casing accommodating the first detection area and the second detection area, the first casing including a first guide hole, and a second casing accommodating the light-emitting element and including a second guide hole aligned with the first guide hole, where the first detection area is configured to receive second light that is emitted by the light-emitting element and reflected by a subject, and the second detection area is configured to receive third light through the first guide hole and the second guide hole, the third light being a portion of the first light.

The light-emitting element assembly may be configured to generate the third light by reflecting or refracting the portion of the first light through the second guide hole.

The light-emitting element assembly may include a collimator and at least one reflector, the collimator and the at least one reflector being configured to reflect or refract the portion of the first light through the second guide hole.

The first casing may include a first accommodation space accommodating the light-emitting element assembly, a second accommodation space accommodating the first detection area, a guide structure between the first accommodation space and the second accommodation space, the guide structure accommodating the second detection area, a first partition between the first accommodation space and the guide structure, and a second partition between the guide structure and the second accommodation space.

The first guide hole may be in the first partition and the second partition may be configured to block the second light from being incident on the second detection area.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a block diagram illustrating an electronic device within a network environment according to one or more embodiments;

FIG. 2 is a front perspective view of an electronic device according to one or more embodiments;

FIG. 3 is a rear perspective view of the electronic device according to one or more embodiments;

FIG. 4 is an exploded perspective view illustrating a front side of an electronic device according to one or more embodiments;

FIG. 5 is an exploded perspective view illustrating a rear side of an electronic device according to one or more embodiments;

FIG. 6 is a perspective view illustrating an optical module according to one or more embodiments;

FIG. 7 is a cross-sectional view illustrating the optical module along line L1 in

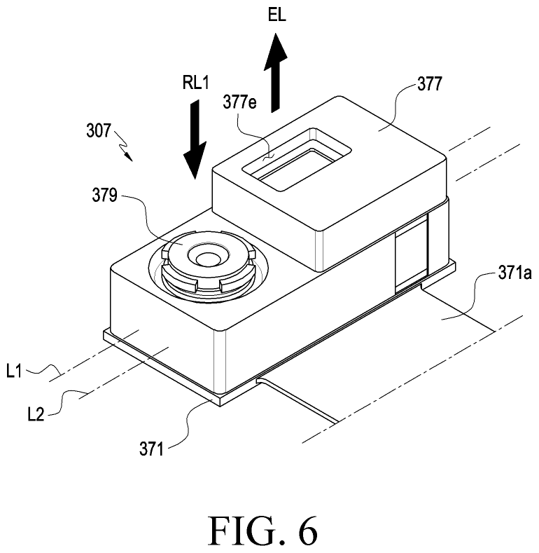

FIG. 6 according to one or more embodiments;

FIG. 8 is a cross-sectional view illustrating the optical module along line L2 in FIG. 6 according to one or more embodiments;

FIG. 9 is a perspective view illustrating a light-emitting assembly of an optical module according to one or more embodiments;

FIG. 10 is a perspective view illustrating a state in which a light-emitting element assembly of an optical module is disposed in a first casing, according to one or more embodiments;

FIG. 11 is a plan view illustrating a portion of a light-emitting element assembly of an optical module according to one or more embodiments;

FIG. 12 is a view illustrating a light-emitting element assembly of an optical module according to one or more embodiments;

FIG. 13 is a view illustrating a path along which reference light of an optical module travels, according to one or more embodiments;

FIG. 14 is a graph showing a first measurement result of an optical module according to one or more embodiments;

FIG. 15 is a graph showing a second measurement result of an optical module according to one or more embodiments;

FIG. 16 is a flowchart illustrating a method of measuring a reception deviation in an optical module according to one or more embodiments;

FIG. 17 is a flowchart illustrating a method of measuring subject distance information using an optical module according to one or more embodiments;

FIG. 18 is a perspective view illustrating an internal configuration of a wearable electronic device according to one or more embodiments;

FIGS. 19 and 20 are views illustrating the front and rear sides of a wearable electronic device according to one or more embodiments; and

FIG. 21 is a diagram illustrating a portion of a wearable electronic device according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

The terms and words used in the following description and claims are not limited to bibliographical meanings, but may be used to clearly and consistently describe the various embodiments set forth herein. Therefore, it will be apparent to those skilled in the art that the following description of various implementations of the disclosure is provided only for the purpose of explanation, rather than for the purpose of limiting the disclosure defined as the scope of protection and equivalents thereto.

It should be appreciated that a singular form such as “a,” “an,” or “the” also includes the meaning as a plural form, unless the context clearly indicates otherwise. Therefore, for example, “a component surface” may indicate one or more of component surfaces.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

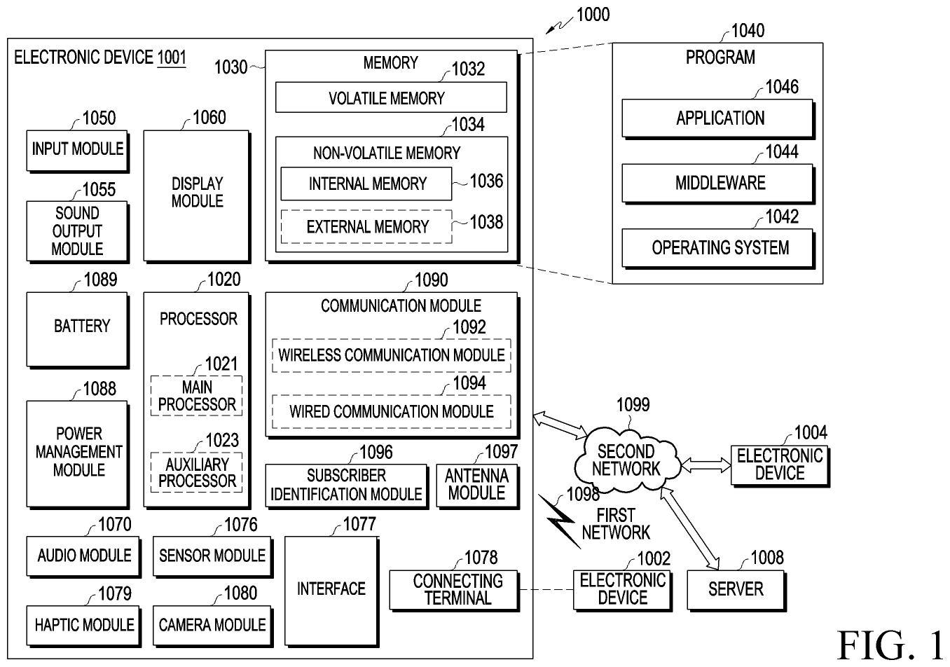

FIG. 1 is a block diagram illustrating an electronic device 1001 in a network environment 1000 according to various embodiments. Referring to FIG. 1, the electronic device 1001 in the network environment 1000 may communicate with an electronic device 1002 via a first network 1098 (e.g., a short-range wireless communication network), or at least one of an electronic device 1004 or a server 1008 via a second network 1099 (e.g., a long-range wireless communication network). According to an embodiment, the electronic device 1001 may communicate with the electronic device 1004 via the server 1008. According to an embodiment, the electronic device 1001 may include a processor 1020, memory 1030, an input module 1050, a sound output module 1055, a display module 1060, an audio module 1070, a sensor module 1076, an interface 1077, a connecting terminal 1078, a haptic module 1079, a camera module 1080, a power management module 1088, a battery 1089, a communication module 1090, a subscriber identification module (SIM) 1096, or an antenna module 1097. In some embodiments, at least one of the components (e.g., the connecting terminal 1078) may be omitted from the electronic device 1001, or one or more other components may be added in the electronic device 1001. In some embodiments, some of the components (e.g., the sensor module 1076, the camera module 1080, or the antenna module 1097) may be implemented as a single component (e.g., the display module 1060).

The processor 1020 may execute, for example, software (e.g., a program 1040) to control at least one other component (e.g., a hardware or software component) of the electronic device 1001 coupled with the processor 1020, and may perform various data processing or computation. According to an embodiment, as at least part of the data processing or computation, the processor 1020 may store a command or data received from another component (e.g., the sensor module 1076 or the communication module 1090) in volatile memory 1032, process the command or the data stored in the volatile memory 1032, and store resulting data in non-volatile memory 1034. According to an embodiment, the processor 1020 may include a main processor 1021 (e.g., a central processing unit (CPU) or an application processor (AP)), or an auxiliary processor 1023 (e.g., a graphics processing unit (GPU), a neural processing unit (NPU), an image signal processor (ISP), a sensor hub processor, or a communication processor (CP)) that is operable independently from, or in conjunction with, the main processor 1021. For example, when the electronic device 1001 includes the main processor 1021 and the auxiliary processor 1023, the auxiliary processor 1023 may be adapted to consume less power than the main processor 1021, or to be specific to a specified function. The auxiliary processor 1023 may be implemented as separate from, or as part of the main processor 1021.

The auxiliary processor 1023 may control at least some of functions or states related to at least one component (e.g., the display module 1060, the sensor module 1076, or the communication module 1090) among the components of the electronic device 1001, instead of the main processor 1021 while the main processor 1021 is in an inactive (e.g., sleep) state, or together with the main processor 1021 while the main processor 1021 is in an active state (e.g., executing an application). According to an embodiment, the auxiliary processor 1023 (e.g., an ISP or a CP) may be implemented as part of another component (e.g., the camera module 1080 or the communication module 1090) functionally related to the auxiliary processor 1023. According to an embodiment, the auxiliary processor 1023 (e.g., the neural processing unit) may include a hardware structure specified for artificial intelligence model processing. An artificial intelligence model may be generated by machine learning. Such learning may be performed, e.g., by the electronic device 1001 where the artificial intelligence is performed or via a separate server (e.g., the server 1008). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 1030 may store various data used by at least one component (e.g., the processor 1020 or the sensor module 1076) of the electronic device 1001. The various data may include, for example, software (e.g., the program 1040) and input data or output data for a command related thereto. The memory 1030 may include the volatile memory 1032 or the non-volatile memory 1034.

The program 1040 may be stored in the memory 1030 as software, and may include, for example, an operating system (OS) 1042, middleware 1044, or an application 1046.

The input module 1050 may receive a command or data to be used by another component (e.g., the processor 1020) of the electronic device 1001, from the outside (e.g., a user) of the electronic device 1001. The input module 1050 may include, for example, a microphone, a mouse, a keyboard, a key (e.g., a button), or a digital pen (e.g., a stylus pen).

The sound output module 1055 may output sound signals to the outside of the electronic device 1001. The sound output module 1055 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 1060 may visually provide information to the outside (e.g., a user) of the electronic device 1001. The display module 1060 may include, for example, a display, a hologram device, or a projector and control circuitry to control a corresponding one of the display, hologram device, and projector. According to an embodiment, the display module 1060 may include a touch sensor adapted to detect a touch, or a pressure sensor adapted to measure the intensity of force incurred by the touch.

The audio module 1070 may convert a sound into an electrical signal and vice versa. According to an embodiment, the audio module 1070 may obtain the sound via the input module 1050, or output the sound via the sound output module 1055 or a headphone of an external electronic device (e.g., an electronic device 1002) directly (e.g., wiredly) or wirelessly coupled with the electronic device 1001.

The sensor module 1076 may detect an operational state (e.g., power or temperature) of the electronic device 1001 or an environmental state (e.g., a state of a user) external to the electronic device 1001, and then generate an electrical signal or data value corresponding to the detected state. According to an embodiment, the sensor module 1076 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 1077 may support one or more specified protocols to be used for the electronic device 1001 to be coupled with the external electronic device (e.g., the electronic device 1002) directly (e.g., wiredly) or wirelessly. According to an embodiment, the interface 1077 may include, for example, a high definition multimedia interface (HDMI), a universal serial bus (USB) interface, a secure digital (SD) card interface, or an audio interface.

A connecting terminal 1078 may include a connector via which the electronic device 1001 may be physically connected with the external electronic device (e.g., the electronic device 1002). According to an embodiment, the connecting terminal 1078 may include, for example, a HDMI connector, a USB connector, a SD card connector, or an audio connector (e.g., a headphone connector).

The haptic module 1079 may convert an electrical signal into a mechanical stimulus (e.g., a vibration or a movement) or electrical stimulus which may be recognized by a user via his tactile sensation or kinesthetic sensation. According to an embodiment, the haptic module 1079 may include, for example, a motor, a piezoelectric element, or an electric stimulator.

The camera module 1080 may capture a still image or moving images. According to an embodiment, the camera module 1080 may include one or more lenses, image sensors, ISPs, or flashes.

The power management module 1088 may manage power supplied to the electronic device 1001. According to an embodiment, the power management module 1088 may be implemented as at least part of, for example, a power management integrated circuit (PMIC).

The battery 1089 may supply power to at least one component of the electronic device 1001. According to an embodiment, the battery 1089 may include, for example, a primary cell which is not rechargeable, a secondary cell which is rechargeable, or a fuel cell.

The communication module 1090 may support establishing a direct (e.g., wired) communication channel or a wireless communication channel between the electronic device 1001 and the external electronic device (e.g., the electronic device 1002, the electronic device 1004, or the server 1008) and performing communication via the established communication channel. The communication module 1090 may include one or more communication processors that are operable independently from the processor 1020 (e.g., the AP) and supports a direct (e.g., wired) communication or a wireless communication. According to an embodiment, the communication module 1090 may include a wireless communication module 1092 (e.g., a cellular communication module, a short-range wireless communication module, or a global navigation satellite system (GNSS) communication module) or a wired communication module 1094 (e.g., a local area network (LAN) communication module or a power line communication (PLC) module). A corresponding one of these communication modules may communicate with the external electronic device via the first network 1098 (e.g., a short-range communication network, such as Bluetooth™, wireless-fidelity (Wi-Fi) direct, or infrared data association (IrDA)) or the second network 1099 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 1092 may identify and authenticate the electronic device 1001 in a communication network, such as the first network 1098 or the second network 1099, using subscriber information (e.g., international mobile subscriber identity (IMSI)) stored in the subscriber identification module 1096.

The wireless communication module 1092 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 1092 may support a high-frequency band (e.g., the mmWave band) to achieve, e.g., a high data transmission rate. The wireless communication module 1092 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 1092 may support various requirements specified in the electronic device 1001, an external electronic device (e.g., the electronic device 1004), or a network system (e.g., the second network 1099). According to an embodiment, the wireless communication module 1092 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 1097 may transmit or receive a signal or power to or from the outside (e.g., the external electronic device) of the electronic device 1001. According to an embodiment, the antenna module 1097 may include an antenna including a radiating element composed of a conductive material or a conductive pattern formed in or on a substrate (e.g., a printed circuit board (PCB)). According to an embodiment, the antenna module 1097 may include a plurality of antennas (e.g., array antennas). In such a case, at least one antenna appropriate for a communication scheme used in the communication network, such as the first network 1098 or the second network 1099, may be selected, for example, by the communication module 1090 (e.g., the wireless communication module 1092) from the plurality of antennas. The signal or the power may then be transmitted or received between the communication module 1090 and the external electronic device via the selected at least one antenna. According to an embodiment, another component (e.g., a radio frequency integrated circuit (RFIC)) other than the radiating element may be additionally formed as part of the antenna module 1097.

According to various embodiments, the antenna module 1097 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 1001 and the external electronic device 1004 via the server 1008 coupled with the second network 1099. Each of the electronic devices 1002 or 1004 may be a device of a same type as, or a different type, from the electronic device 1001. According to an embodiment, all or some of operations to be executed at the electronic device 1001 may be executed at one or more of the external electronic devices 1002, 1004, or 1008. For example, if the electronic device 1001 should perform a function or a service automatically, or in response to a request from a user or another device, the electronic device 1001, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 1001. The electronic device 1001 may provide the outcome, with or without further processing of the outcome, as at least part of a reply to the request. To that end, a cloud computing, distributed computing, mobile edge computing (MEC), or client-server computing technology may be used, for example. The electronic device 1001 may provide ultra low-latency services using, e.g., distributed computing or mobile edge computing. In another embodiment, the external electronic device 1004 may include an internet-of-things (IoT) device. The server 1008 may be an intelligent server using machine learning and/or a neural network. According to an embodiment, the external electronic device 1004 or the server 1008 may be included in the second network 1099. The electronic device 1001 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 1040) including one or more instructions that are stored in a storage medium (e.g., internal memory or external memory) that is readable by a machine (e.g., the electronic device). For example, a processor (e.g., the processor) of the machine (e.g., the electronic device) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

In the following detailed description, a length direction, a width direction, and/or a thickness direction of an electronic device may be referred to, where the length direction may be defined as the “Y-axis direction”, the width direction may be defined as the “X-axis direction”, and/or the thickness direction may be defined as the “Z-axis direction”. In one or more embodiments, the direction in which a component is oriented may be mentioned along with the orthogonal coordinate system illustrated in the drawings, as well as the negative/positive symbol “(−/+)”. For example, the front surface of an electronic device and/or a housing may be defined as a “surface oriented in the +Z direction”, and the rear surface may be defined as a “surface oriented in the −Z direction”. In one or more embodiments, a side surface of an electronic device and/or a housing may include an area oriented in the +X direction, an area oriented in the +Y direction, an area oriented in the −X direction, and/or an area oriented in the −Y direction. In one or more embodiments, the “X-axis direction” may include both the “−X direction” and the “+X direction”. It is noted that these are based on the Cartesian coordinate system illustrated in the drawings for the sake of brevity of description, and the descriptions of these directions or components do not limit the embodiments of the disclosure. For example, depending on the design specifications of an electronic device or a user's usage habits, the Cartesian coordinate system may be defined differently from the disclosure.

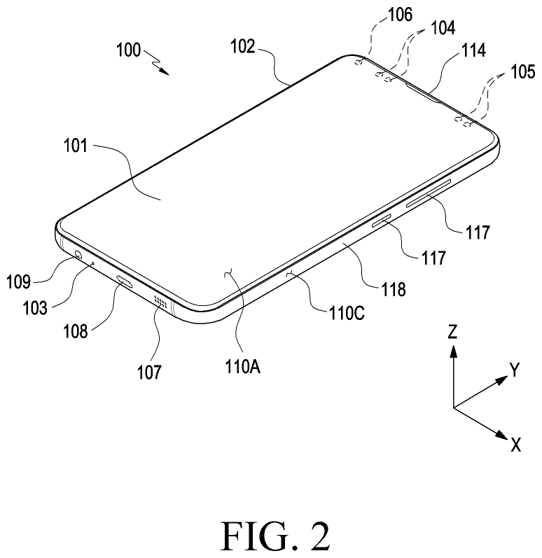

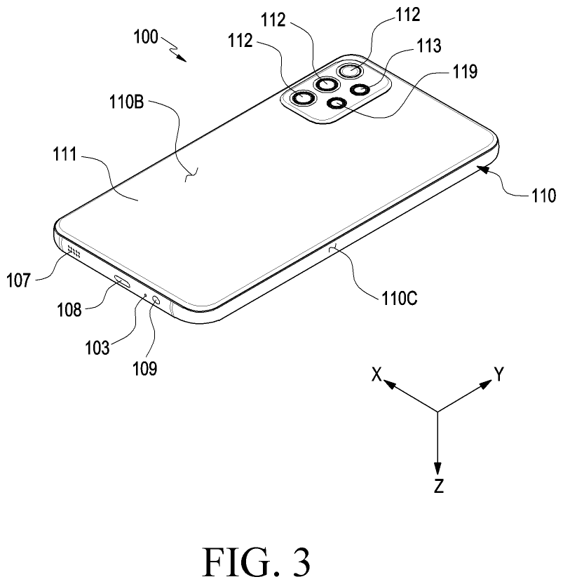

FIG. 2 is a front perspective view of an electronic device 100 according to one or more embodiments. FIG. 3 is a rear perspective view of the electronic device 100 of FIG. 2 according to one or more embodiments.

Referring to FIGS. 2 and 3, the electronic device 100 (e.g., the electronic device 1001 in FIG. 1) according to one or more embodiments may include a housing 110 including a first surface (or the front surface) 110A, a second surface (or the rear surface) 110B, and a side surface 110C surrounding the space between the first surface 110A and the second surface 110B. In one or more embodiments, the housing 110 may refer to a structure that forms a portion of the first surface 110A of FIG. 2, and the second surface 110B and the side surface 110C of FIG. 3. According to one or more embodiments, at least a portion of the first surface 110A may be made of a substantially transparent front surface plate 102 (e.g., a glass plate or a polymer plate including various coating layers). The second surface 110B may be made of a substantially opaque rear surface plate 111. The rear surface plate 111 may be made of, for example, coated or colored glass, ceramic, polymer, metal (e.g., aluminum, stainless steel (STS), or magnesium), or a combination of two or more of these materials. The side surface 110C may be defined by the side surface structure (or a side surface bezel structure) 118 coupled to the front surface plate 102 and the rear surface plate 111 and including metal and/or polymer. In one or more embodiments, the rear surface plate 111 and the side surface structure 118 may be integrated with each other and may include the same material (e.g., a metal material such as aluminum).

The front surface plate 102 may include one or more areas that are curved and extend seamlessly from at least a portion of an edge toward the rear surface plate 111. In one or more embodiments, the front surface plate 102 (or the rear surface plate 111) may include only one of the areas bent and extending toward the rear surface plate 111 (or the front surface plate 102), at one side edge of the first surface 110A. According to one or more embodiments, the front surface plate 102 or the rear surface plate 111 may be substantially flat in shape. For example, the front or rear surface plate may not include an area that is curved and extended. When the bent and extending area is included, the thickness of the electronic device 100 in the portion including the bent and extending area may be smaller than the thicknesses of other portions.

According to one or more embodiments, the electronic device 100 may include at least one of a display 101, an audio module (e.g., a microphone hole 103, an external speaker hole 107, and a call receiver hole 114), a sensor module (e.g., a first sensor module 104, a second sensor module, and a third sensor module 119), a camera module (e.g., a first camera device 105, a second camera device 112, and a flash 113), key input devices 117, a light-emitting element 106, and connector holes (e.g., a first connector hole 108 and a second connector hole 109). In one or more embodiments, in the electronic device 100, at least one of the components (e.g., the key input devices 117 or the light-emitting element 106) may be omitted, or other components may be additionally included.

The display 101 may output a screen or may be visually exposed through, for example, a significant portion of the first surface 110A (e.g., the front surface plate 102). In one or more embodiments, at least a portion of the display 101 may be visually exposed through the front surface plate 102 forming the first surface 110A or through a portion of the side surface 110C. In one or more embodiments, the edge of the display 101 may be formed to be substantially the same as the shape of the periphery of the front surface plate 102 adjacent thereto. In one or more embodiments, the distance between the periphery of the display 101 and the periphery of the front surface plate 102 may be substantially constant in order to enlarge the visually exposed area of the display 101.

In one or more embodiments, recesses or openings may be provided in some portions of the screen display area of the display 101, and one or more of an audio module (e.g., the call receiver hole 114), a sensor module (e.g., the first sensor module 104), a camera module (e.g., the first camera device 105), and a light-emitting element 106 may be aligned with the recesses or the openings. In one or more embodiments, the rear surface of the screen display area of the display 101 may include at least one of an audio module (e.g., the call receiver hole 114), a sensor module (e.g., the first sensor module 104), a camera module (e.g., the first camera device 105), a fingerprint sensor, and a light-emitting element 106. In one or more embodiments, the display 101 may be coupled to or arranged adjacent to a touch-sensitive circuit, a pressure sensor capable of measuring a touch intensity (pressure), and/or a digitizer configured to detect an electromagnetic field-type stylus pen. In one or more embodiments, when the front surface plate 102 or the rear surface plate 111 includes the curved and extended area(s), at least a portion of the sensor modules (e.g., the first sensor module 104 and the third sensor module 119), and/or at least a portion of the key input devices 117 may be arranged in the curved and extended area(s).

The audio modules 103, 107, and 114 may include a microphone hole 103 and speaker holes (e.g., the external speaker hole 107 and the call receiver hole 114). A microphone configured to acquire external sound may be placed inside the microphone hole 103, and in one or more embodiments, a plurality of microphones may be placed to detect the direction of sound. The speaker holes may include an external speaker hole 107 and a call receiver hole 114. In one or more embodiments, the speaker holes (e.g., the external speaker hole 107 and the call receiver hole 114) and the microphone hole 103 may be implemented as a single hole, or a speaker may be included without the speaker holes (e.g., the external speaker hole 107 and the call receiver hole 114) (e.g., a piezo speaker).

The sensor modules may generate electrical signals or data values corresponding to the internal operating states or the external environmental states of the electronic device 100. The sensor modules may include, for example, a first sensor module 104 (e.g., a proximity sensor) and/or a second sensor module (e.g., a fingerprint sensor) disposed on the first surface 110A of the housing 110, and/or a third sensor module 119 disposed on the second surface 110B of the housing 110. The second sensor module (e.g., a fingerprint sensor) may be disposed not only on the first surface 110A (e.g., the display 101) of the housing 110, but also on the second surface 110B or the side surface 110C of the housing 110. The electronic device 100 may further include at least one of, for example, a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor.

The camera modules may include a first camera device 105 disposed on the first surface 110A of the electronic device 100, and a second camera device 112 and/or a flash 113 disposed on the second surface 110B of the electronic device 100. The camera devices (e.g., the first camera device 105 and the second camera device 112) may include one or more lenses, an image sensor, and/or an ISP. The flash 113 may include, for example, a light-emitting diode or a xenon lamp. In one or more embodiments, one or more lenses (e.g., an infrared camera lens, a wide-angle lens, and a telephoto lens) and image sensors may be disposed on one surface of the electronic device 100. In one or more embodiments, the flash 113 may emit infrared rays, and the infrared light emitted by the flash 113 and reflected by a subject may be received through the third sensor module 119. The electronic device 100 or the processor (e.g., the processor 1020 in FIG. 1) of the electronic device 100 may detect distance information to the subject based on the time at which infrared rays are received by the third sensor module 119.

The key input devices 117 may be disposed on the side surface 110C of the housing 110. In one or more embodiments, the electronic device 100 may not include some or all of the above-mentioned key input devices 117, and key input devices 117, which are not included, may be implemented in another form, such as soft keys, on the display 101. In one or more embodiments, the key input devices may include a sensor module disposed on the second surface 110B of the housing 110.

The light-emitting element 106 may be disposed on, for example, the first surface 110A of the housing 110. The light-emitting element 106 may provide, for example, the state information of the electronic device 100 in an optical form. In one or more embodiments, the light-emitting element 106 may provide a light source that is linked to the operation of, for example, a camera module (e.g., the first camera device 105). The light-emitting element 106 may include, for example, a light-emitting diode (LED), an infrared LED, and a xenon lamp.

The connector holes (e.g., a first connector hole 108 and a second connector hole 109) may include a first connector hole 108, which is capable of accommodating a connector (e.g., a USB connector) configured to transmit/receive power and/or data to/from an external electronic device (e.g., the electronic device 1002 in FIG. 1), and/or a second connector hole (e.g., an earphone jack) 109, which is capable of accommodating a connector for transmitting/receiving an audio signal to/from an external electronic device.

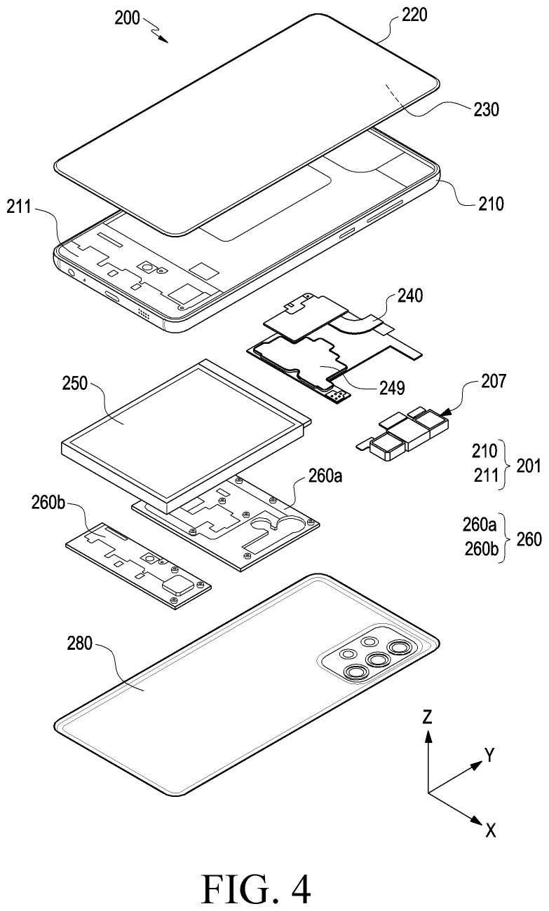

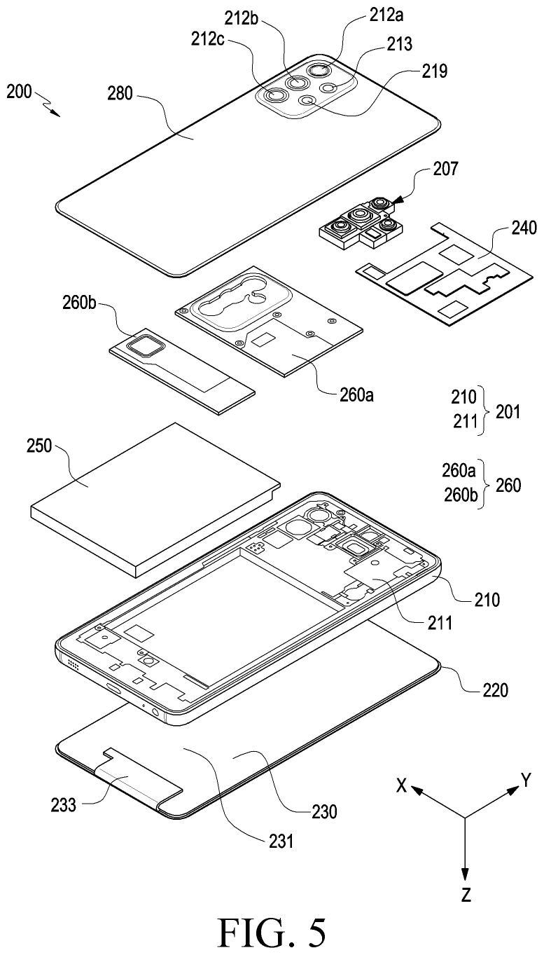

FIG. 4 is an exploded perspective view illustrating the front side of an electronic device 200 (e.g., the electronic device 100 illustrated in FIG. 2) according to one or more embodiments. FIG. 5 is an exploded perspective view illustrating the rear side of the electronic device 200 (e.g., the electronic device 100 illustrated in FIG. 3) according to one or more embodiments.

Referring to FIGS. 4 and 5, the electronic device 200 (e.g., the electronic device 1001, 1002, 1004, or 100 in FIG. 1, 2, or 3) may include a side surface structure 210, a first support member 211 (e.g., a bracket), a front surface plate 220 (e.g., the front surface plate 102 in FIG. 2), a display 230 (e.g., the display 101 in FIG. 2), a printed circuit board (or a substrate assembly) 240, a battery 250, a second support member 260 (e.g., a rear case), an antenna (e.g., the antenna module 1097 in FIG. 1), a camera assembly 207, and a rear surface plate 280 (e.g., the rear surface plate 111 in FIG. 3). In one or more embodiments, in the electronic device 200, at least one of the components (e.g., the first support member 211 or the second support member 260) may be omitted, or other components may be additionally included. At least one of the components of the electronic device 200 may be the same as or similar to at least one of the components of the electronic device 100 of FIG. 2 or 3, and a redundant description thereof may be omitted below.

The first support member 211 may be arranged inside the electronic device 200 to be connected to the side surface structure 210 or may be integrated with the side surface structure 210. The first support member 211 may be made of, for example, a metal material and/or a non-metal (e.g., polymer) material. When at least partially being made of a metal material, a portion of the side surface structure 210 or the first support member 211 may serve as an antenna. The first support member 211 may include one surface to which the display 230 is coupled and the other surface to which the printed circuit board 240 is coupled. A processor (e.g., the processor 1020 in FIG. 1), memory (e.g., the memory 1030 in FIG. 1), and/or an interface (e.g., the interface 1077 in FIG. 1) may be mounted on the printed circuit board 240. The processor may include one or more of, for example, a CPU, an AP, a GPU, an ISP, a sensor hub processor, or a CP. In one or more embodiments, the processor and/or the memory may refer to one of the circuit devices mounted on an integrated circuit chip.

According to one or more embodiments, the first support member 211 and the side surface structure 210 may be combined to be referred to as a front case or a housing 201. According to one or more embodiments, the housing 201 may be generally understood as a structure for accommodating, protecting, or disposing the printed circuit board 240 or the battery 250. In one or more embodiments, it may be understood that the housing 201 includes structures capable of being visually or tactfully recognized by a user in the exterior of the electronic device 200, such as the side surface structure 210, the front surface plate 220, and/or the rear surface plate 280. In one or more embodiments, the front surface or rear surface of the housing 201 may refer to the first surface 110A in FIG. 2 or the second surface 110B in FIG. 3. In one or more embodiments, the first support member 211 may be disposed between the front surface plate 220 (e.g., the first surface 110A in FIG. 1) and the rear surface plate 280 (e.g., the second surface 110B in FIG. 3) and may serve as a structure on which electrical/electronic components, such as a printed circuit board 240 or a camera assembly 207, are arranged.

The display 230 may include a display panel 231 and a flexible printed circuit board 233 extending from the display panel 231. The flexible printed circuit board 233 may be understood, for example, to be electrically connected to the display panel 231 while being disposed at least partially on the rear surface of the display panel 231. In one or more embodiments, reference number 231 may be understood as denoting a protective sheet disposed on the rear surface of the display panel. For example, unless otherwise classified in the following detailed description, the protective sheet may be understood as being a portion of the display panel 231. In one or more embodiments, the protective sheet may function as a buffer structure (e.g., a low-density elastic material such as a sponge) absorbing an external force or an electromagnetic shield structure (e.g., a copper sheet (CU sheet)). According to one or more embodiments, the display 230 may be disposed on the inner surface of the front surface plate 220 and may include a light-emitting layer to output a screen through at least a portion of the first surface 110A of FIG. 2 or the front surface plate 220. As mentioned above, the display 230 may output a screen through substantially the entire area of the first surface 110A of FIG. 2 or the front surface plate 220.

The memory may include, for example, volatile memory or non-volatile memory.

The interface may include, for example, HDMI, USB, SD, and/or an audio interface. For example, the interface may electrically or physically connect the electronic device 200 to an external electronic device, and include a USB connector, an SD card/MMC connector, or an audio connector.

The second support member 260 may include, for example, an upper support member 260a and a lower support member 260b. In one or more embodiments, the upper support member 260a may be arranged to surround the printed circuit board 240 together with a portion of the first support member 211. For example, the printed circuit board 240 may be arranged substantially between the first support member 211 and the second support member 260 (e.g., the upper support member 260a). A circuit device implemented in the form of an integrated circuit chip (e.g., a processor, a communication module, or memory) or various electrical/electronic components may be disposed on the printed circuit board 240, and in one or more embodiments, the printed circuit board 240 may be provided with an electromagnetically shielded environment from the upper support member 260a. In one or more embodiments, at least one shield can 249 may be disposed on the printed circuit board 240. For example, the shield can 249 may provide an electromagnetic shielding environment to a portion or space on the printed circuit board 240. In one or more embodiments, the shield can 249 may be arranged to surround at least a portion of a processor, memory, and/or an integrated circuit chip having a communication module mounted thereon.

According to one or more embodiments, the lower support member 260b may be used as a structure on which electric/electronic components, such as a speaker module and an interface (e.g., a USB connector, an SD card/MMC connector, or an audio connector), are arranged. In one or more embodiments, electrical/electronic components, such as a speaker module and an interface (e.g., a USB connector, an SD card/MMC connector, or an audio connector), may be disposed on an additional printed circuit board. For example, the lower support member 260b may be arranged to surround the additional printed circuit board together with the other portion of the first support member 211. The speaker module or interface disposed on the additional printed circuit board or the lower support member 260b may be arranged to correspond to the audio module of FIG. 2 (e.g., the microphone hole 103 or the speaker holes (e.g., the external speaker hole 107 and the call receiver hole 114)) or the connector holes (e.g., the first connector hole 108 and the second connector hole 109).

The battery 250 is a device for supplying power to at least one of the components of the electronic device 200 and may include, for example, a non-rechargeable primary battery, a rechargeable secondary battery, or a fuel cell. At least a portion of the battery 250 may be disposed on substantially the same plane as, for example, the printed circuit board 240. The battery 250 may be integrally disposed inside the electronic device 200, or may be disposed to be detachable from the electronic device 200.

The antenna may include a conductive pattern implemented on the surface of the first support member 211 and/or the surface of the second support member 260, for example, through laser direct structuring (LDS) techniques. In one or more embodiments, the antenna may include a printed circuit pattern provided on the surface of a thin film, and the thin film-type antenna may be disposed between the rear surface plate 280 and the battery 250. The antenna may include, for example, a near-field communication (NFC) antenna, a wireless charging antenna, and/or a magnetic secure transmission (MST) antenna. The antenna may, for example, perform short-distance communication with an external device, or wirelessly transmit and receive power required for charging. In one or more embodiments, an antenna structure may be configured with a portion or a combination of the side surface structure 210 and/or the first support member 211.

The camera assembly 207 may include at least one camera module. Inside the electronic device 200, the camera assembly 207 may receive at least a portion of light incident through optical holes or camera windows 212a, 212b, 212c, 213, and 219. In one or more embodiments, the camera assembly 207 may be disposed on the first support member 211 at a position adjacent to the printed circuit board 240. In one or more embodiments, the camera module(s) of the camera assembly 207 may be generally aligned with one of the camera windows 212a, 212b, 212c, 213, and 219, and may be at least partially surrounded by the second support member 260 (e.g., the upper support member 260a). When the electronic device 200 may include a distance information detection function, a portion of the camera assembly 207 may include a light-emitting element. In one or more embodiments, when the electronic device 200 includes a distance information detection function, additional light-emitting elements and/or additional light-receiving elements may be provided to the camera assembly 207.

The above-described configurations of the electronic devices 1001, 1002, 1004, 100, and 200 may be referred to in the description below. Even if not directly mentioned, the configurations of the embodiments described above may be similarly applied to the embodiments described below. The exemplified electronic device is a bar-type device, but the embodiments of the disclosure are not limited thereto, and the optical module described below may be arranged in a foldable-type, a rollable-type, and/or a slide-type device in a similar or substantially identical manner.

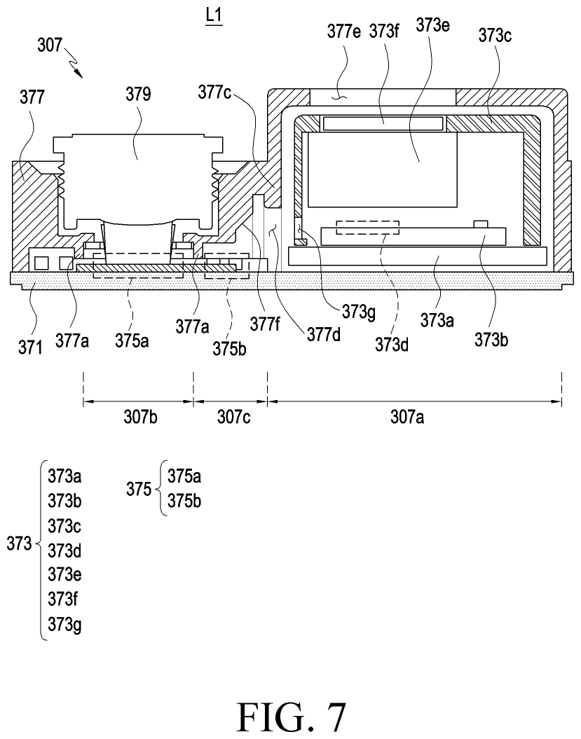

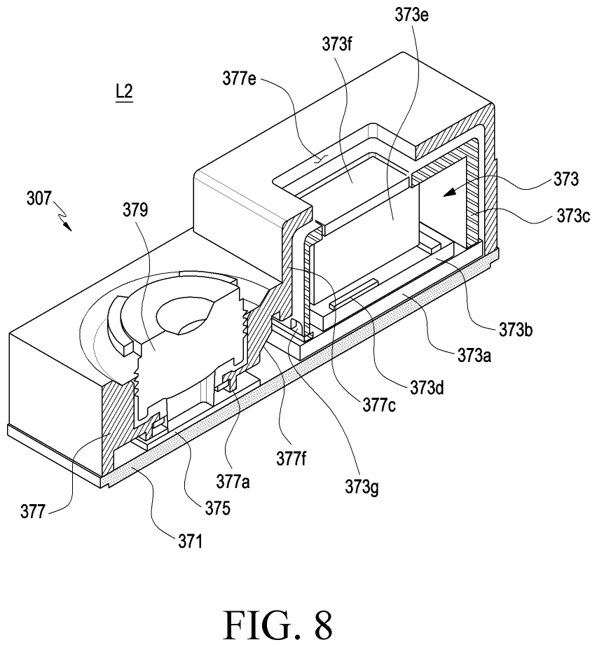

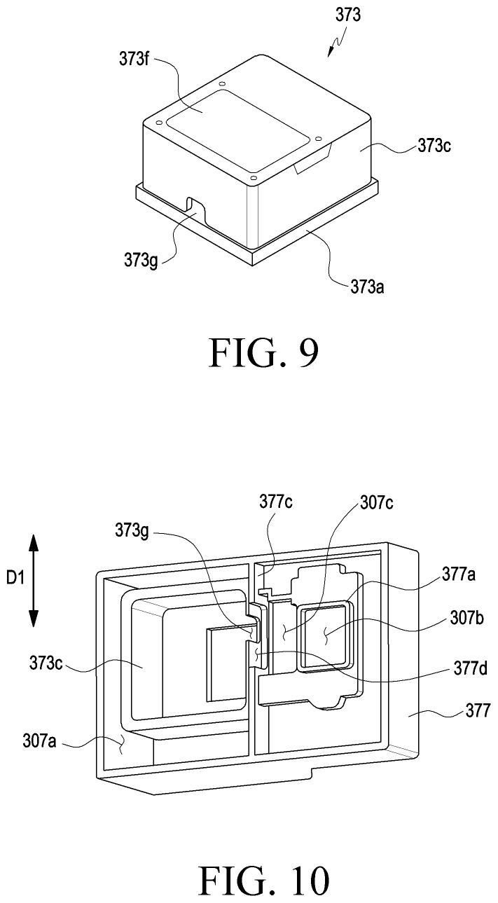

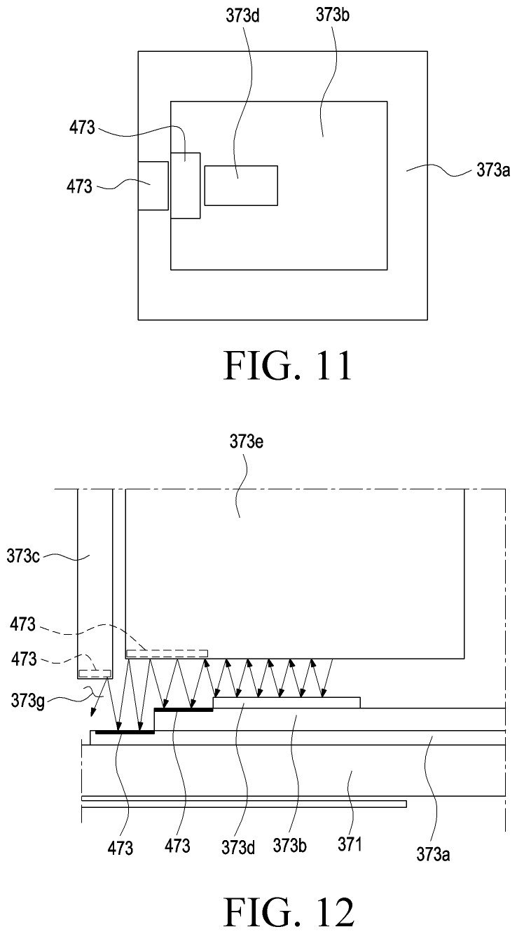

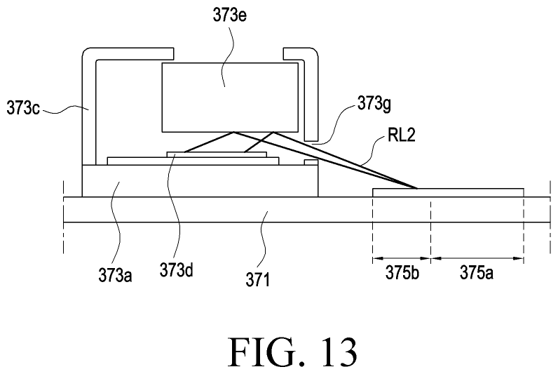

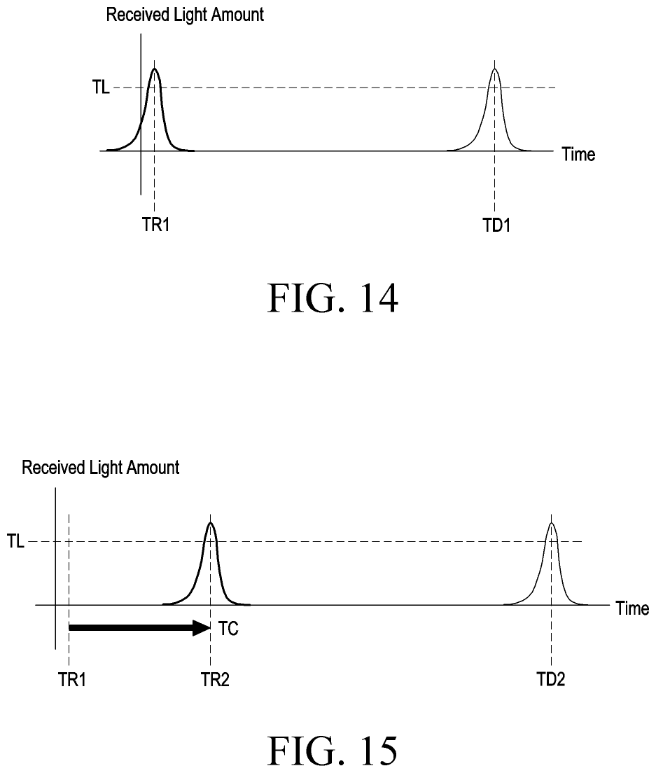

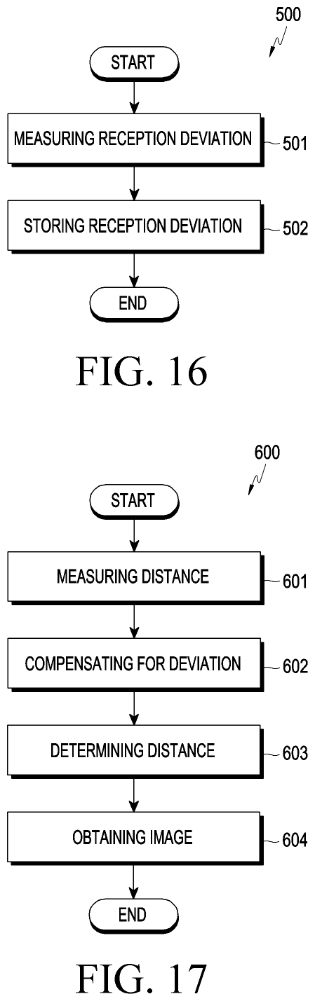

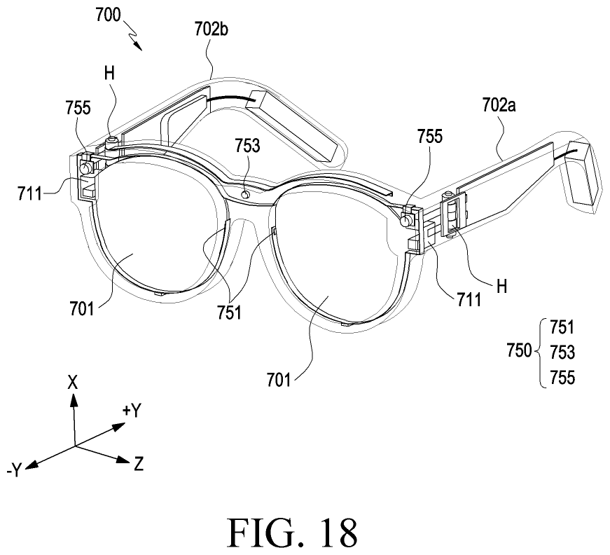

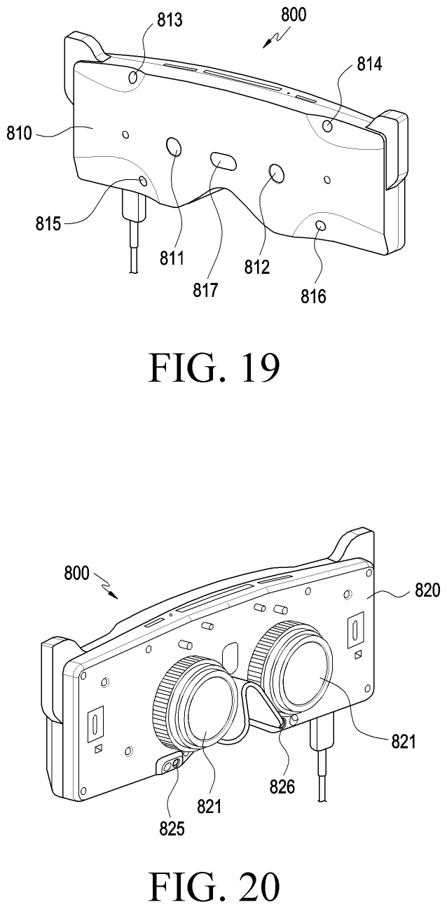

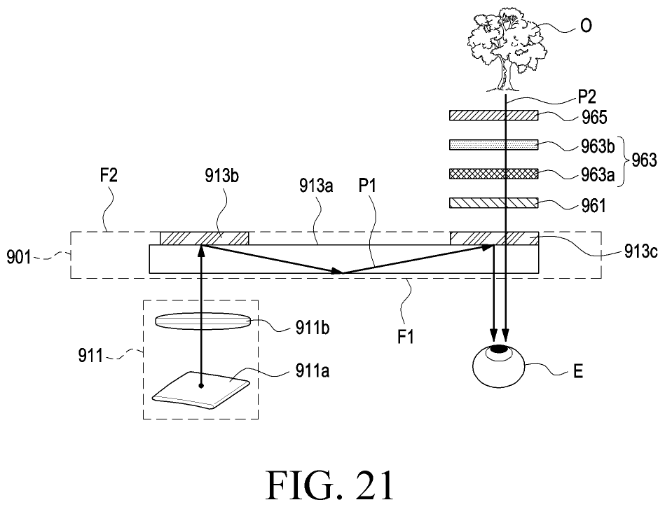

FIG. 6 is a perspective view illustrating an optical module 307 according to one or more embodiments. FIG. 7 is a cross-sectional view illustrating the optical module 307 taken along line L1 in FIG. 6 according to one or more embodiments. FIG. 8 is a cross-sectional view illustrating the optical module 307 taken along line L2 in FIG. 6 according to one or more embodiments.

Referring to FIGS. 6 to 8, the optical module 307 may include a first substrate 371, a light-emitting element assembly 373, a light-receiving element 375, and/or a first casing 377. In one or more embodiments, the optical module 307 may include a flexible printed circuit board 371a. The flexible printed circuit board 371a may be electrically connected to a main circuit board (e.g., the printed circuit board 240 in FIG. 4 or 5) by extending from, for example, the first substrate 371. In one or more embodiments, the light-receiving element 375 may include a first detection area 375a configured to receive first light RL1 that is emitted by the light-emitting element assembly 373 (i.e., EL) and then reflected by the subject. In one or more embodiments, the light-receiving element 375 may include a second detection area 375b configured to receive second light RL2 (e.g., the second light RL2 in FIG. 13) that is a portion of the light emitted by the light-emitting element 373d and guided through a path within the optical module 307. For example, the light-receiving element 375 may receive light (e.g., the first light RL1 and the second light RL2) incident through at least two different paths, and the optical module 307 and/or the electronic device (e.g., electronic device 1001, 1002, 1004, 100, or 200 in FIGS. 1 to 5) may determine the subject distance based on the light received by the light-receiving element 375.

According to one or more embodiments, by including a first casing 377, the optical module 307 may guide a portion of the light (e.g., the second light RL2 in FIG. 13) output from the light-emitting element assembly 373 to the light-receiving element 375 (e.g., the second detection area 375b) through an independent path relative to the light emitted toward the subject (e.g., the emitted light EL). In one or more embodiments, the second light RL2 may be at least a portion of the light that is reflected or refracted within the first casing 377 and not emitted toward the subject. In one or more embodiments, it may be understood that the internal structure or internal shape of the first casing 377 guides or directs a portion of the light output from the light-emitting element assembly 373 (e.g., the second light RL2 of FIG. 13) to the light-receiving element 375.

According to one or more embodiments, the first substrate 371 may be a mechanical structure configured to arrange the light-emitting element assembly 373, the light-receiving element 375, and/or the first casing 377, and may provide wiring for transmitting power or electrical signals to the light-emitting element assembly 373 and the light-receiving element 375. In one or more embodiments, the first substrate 371 may be electrically connected to another component (e.g., the printed circuit board (or substrate assembly) 240 in FIG. 4 or FIG. 5) via a flexible printed circuit board. An active or passive element other than the light-emitting element assembly 373 or the light-receiving element 375 may be arranged on the first substrate 371. In one or more embodiments, the first substrate 371 may be made of a dielectric material or a ceramic material (e.g., low temperature co-fired ceramic (LTCC) or high temperature co-fired ceramic (HTCC)). For example, the first substrate 371 may be manufactured from a material with high thermal conductivity, such as ceramic, and may be manufactured from a material other than ceramic, considering specifications or manufacturing costs required by the optical module 307 and/or the electronic device (e.g., electronic device (1001, 1002, 1004, 100, or 200 in FIGS. 1 to 5).

According to one or more embodiments, the light-emitting element assembly 373 may be arranged on the first substrate 371 to receive power or a control signal, and configured to emit light of a predetermined wavelength band. For example, when the optical module 307 is used to detect distance information, the light-emitting element assembly 373 may be configured to emit laser light of an infrared wavelength band. In one or more embodiments, the light-emitting element assembly 373 may include a second substrate 373a including a ceramic material (e.g., LTCC or HTCC), a driving circuit (e.g., an integrated circuit chip 373b) mounted on the second substrate 373a, and/or a light-emitting element 373d. The light-emitting element 373d may be configured to emit light of a predetermined wavelength band by being controlled by the driving circuit. In one or more embodiments, when the optical module 307 is used to detect distance information, the light-emitting element 373d may emit infrared laser light. In one or more embodiments, the light-emitting element 373d may include a vertical cavity surface emitting laser (VCSEL). In one or more embodiments, the light output from the light-emitting element 373d may be substantially provided as radiant light EL, and a portion of the light output from the light-emitting element 373d may be incident on the second detection area 375b inside the first casing 377.

According to one or more embodiments, the second substrate 373a may be a structure configured to arrange thereon an integrated circuit chip 373b having a driving circuit built therein and/or a light-emitting element 373d, and may provide wiring for transmitting power or an electric signal to the integrated circuit chip 373b and/or the light-emitting element 373d. An active or passive element other than the driving circuit or the light-emitting element 373d may be arranged on the second substrate 373a. In one or more embodiments, the second substrate 373a may be made of a ceramic material (e.g., LTCC or HTCC). For example, the second substrate 373a may be made of LTCC or HTCC with high thermal conductivity, thereby allowing the generated heat (e.g., heat generated by the light-emitting element 373d) to be quickly dispersed to another structure or another area.

According to one or more embodiments, the light-emitting element assembly 373 may be placed on the first substrate 371 through surface mounting technology (SMT). For example, the driving circuit and the light-emitting element 373d may be arranged on the second substrate 373a and assembled to the first substrate 371. In one or more embodiments, the light-emitting element assembly 373 may further include a second casing 373c, thereby preventing the light-emitting element 373d or the integrated circuit chip 373b from being damaged while being assembled to the first substrate 371. For example, the second casing 373c may be disposed on the second substrate 373a in the state of accommodating the integrated circuit chip 373b and/or the light-emitting element 373d. With the second casing 373c disposed thereon, the second substrate 373a may be at least partially exposed to the external space of the light-emitting element assembly 373, thereby allowing heat generated inside the second casing 373c to be moved or released outside the second casing 373c.

According to one or more embodiments, the light-emitting element assembly 373 may further include a first guide hole 373g provided in the second casing 373c. The first guide hole 373g may be disposed, for example, between the light-emitting element 373d and the light-receiving element 375 (e.g., the second detection area 375b). In one or more embodiments, a portion of the light output from the light-emitting element 373d may not be emitted outside the optical module 307 but may be reflected or refracted by another structure inside the second casing 373c and guided to the second detection area 375b through the first guide hole 373g. In one or more embodiments, the position or size of the first guide hole 373g may be implemented in various ways in consideration of the relative positions of the light-emitting element 373d and the second detection area 375b, and/or the path of the light reflected or refracted within the second casing 373c.

According to one or more embodiments, when the light-emitting element 373d emits infrared laser light for detecting distance information, the optical module 307 and/or the light-emitting element assembly 373 may include optical element(s), such as a diffractive optical element (DOE) 373f and/or a collimator 373e. For example, by providing optical elements such as a diffractive optical element and/or a collimator, at least a portion of the light output from the light-emitting element 373d may be guided or aligned in a predetermined direction. Here, the direction in which the output light is aligned may refer to the direction in which a camera (e.g., the camera assembly 207 in FIG. 4 or 5) is directed when photographing a subject. In one or more embodiments, an optical element, such as a diffractive optical element 373f or a collimator 373e, may be placed in another structure, such as an opening 377e of the first casing 377. In one or more embodiments, the optical element, such as the diffractive optical element 373f or the collimator 373e, is a component that aligns or focuses light (e.g., emitted light EL) emitted from the light-emitting element 373d, and may be arranged in the light-emitting element assembly 373 (e.g., the second casing 373c), thereby allowing the direction of propagation of the emitted light EL to be easily configured.

According to one or more embodiments, a diffractive optical element and a collimator are exemplified as optical elements for aligning output light, but the embodiments of the disclosure are not limited thereto. The types or number of optical elements may be implemented differently from the exemplified embodiments depending on the specifications required for the optical module 307. For example, the diffractive optical element and the collimator may be replaced with optical elements such as meta-lens, or additional optical elements not mentioned above may be optionally combined. In one or more embodiments, when including the diffractive optical element and/or the collimator, the optical elements may be aligned and/or fixed at predetermined positions relative to the light-emitting element 373d in accordance with design specifications during the process of assembling the light-emitting element assembly 373.

In one or more embodiments, as mentioned above, the light-receiving element 375 may include a first detection area 375a configured to receive light incident from the exterior, and a second detection area 375b provided on one side (i.e., adjacent to one side) of the first detection area 375a. The light received by the first detection area 375a may be, for example, the first light RL1 that is reflected by the subject after being emitted by the light-emitting element assembly 373. In one or more embodiments, the second detection area 375b may detect at least a portion of light reflected or refracted inside the second casing 373c from the light emitted by the light-emitting element 373d. For example, most of the light output by the light-emitting element 373d at a predetermined time may be reflected by the subject and detected by the first detection area 375a, and a portion of the light output by the light-emitting element 373d at the predetermined time may travel through the interior of the first casing 377 and may be detected by the second detection area 375b.

According to one or more embodiments, the optical module 307 and/or the electronic device may determine the subject distance from the time period from the time at which light is emitted from the light-emitting element assembly 373 to the time at which the first detection area 375a receives the first light RL1. In one or more embodiments, the time at which light is emitted from the light-emitting element assembly 373 may be determined based on the time at which the second detection area 375b receives the second light RL2 under the condition of substantially performing an operation of detecting distance information. For example, the distance information may be determined based on the time period from the time at which the second light RL2 reaches the second detection area 375b to the time at which the first light RL1 reaches the first detection area 375a. In one or more embodiments, when the amount of light (e.g., the amount of the first light RL1 and/or the amount of the second light RL2) reaching the first detection area 375a and/or the second detection area 375b satisfies a predetermined level (e.g., “TL” in FIG. 14 or 15), the time at which light is emitted from the light-emitting element assembly 373 may be determined and/or the subject distance may be determined. In one or more embodiments, the light-emitting element assembly 373 emits the first light RL1 in the form of about 60,000 or more pulses toward the subject, and the time at which the first light RL1 is received or the subject distance may be determined based on the time at which the largest number of pulses are received in the first detection area 375a. The determination of the time or distance may suppress noise caused by interference from natural light or reflected light incident from an unintended direction.

According to one or more embodiments, when there is a deviation due to the operating environment (e.g., temperature), the deviation of the arrival time of the first light RL1 may be substantially the same as the deviation of the arrival time of the second light RL2. For example, even if there is a deviation due to the operating environment, when determining information about the distance based on the times at which the first light RL1 and the second light RL2 arrive, distortion of distance information due to the operating environment may be suppressed. This will be described again with reference to FIGS. 14 and 15. For example, since a deviation in the operating environment, such as temperature, may occur substantially equally between the arrival time of the first light RL1 and the arrival time of the second light RL2, when determining the distance to the subject based on the time difference between the arrival time of the first light RL1 in the first detection area 375a and the arrival time of the second light RL2 in the second detection area 375b, the deviation in distance measurement due to the operating environment may be suppressed.

According to one or more embodiments, the first casing 377 may include a first accommodation space 307a configured to accommodate the light-emitting element assembly 373, a second accommodation space 307b configured to accommodate at least a portion of the first detection area 375a, and/or a guide structure 307c arranged between the first accommodation space 307a and the second accommodation space 307b. In one or more embodiments, when the first detection area 375a is arranged in the second accommodation space 307b, at least a portion of the second detection area 375b may be arranged inside the guide structure 307c. For example, the second accommodation space 307b and the guide structure 307c may be provided as an area (or space) that accommodates the light-receiving element 375. In one or more embodiments, the light-emitting element assembly 373 may be disposed in the first accommodation space 307a in the state in which the first guide hole 373g is aligned with the guide structure 307c. Therefore, the first guide hole 373g may function as a path for guiding the second light RL2 from the interior of the second casing 373c to the interior of the guide structure 307c. In one or more embodiments, the guide structure 307c may function as a structure for guiding or directing the second light RL2 to be incident on the second detection area 375b by being aligned with the first guide hole 373g. In one or more embodiments, the first casing 377 may be placed on the first substrate 371 in the state in which the light-emitting element assembly 373 and the light-receiving element 375 are placed on the first substrate 371 by surface mounting technology.

According to one or more embodiments, the first casing 377 may include a first partition 377c disposed between the guide structure 307c and the first accommodation space 307a and/or a second partition 377a disposed between the guide structure 307c and the second accommodation space 307b. In one or more embodiments, the first partition 377c may be a portion of a structure that substantially guides the assembly position of the light-emitting element assembly 373. For example, the first partition 377c may extend from the inner surface of the first casing 377 toward the first substrate 371, and a portion of the outer surface of the light-emitting element assembly 373 (e.g., the second casing 373c) may be arranged to substantially face the first partition 377c. In one or more embodiments, the second partition 377a may be arranged to extend from the inner surface of the first casing 377 between the guide structure 307c and the second accommodation space 307b and to face the first substrate 371 and/or the light-receiving element 375. In one or more embodiments, the second partition 377a may be positioned to at least partially correspond to the boundary between the first detection area 375a and the second detection area 375b.

According to one or more embodiments, the first partition 377c may provide a second guide hole 377d aligned with the first guide hole 373g. The second guide hole 377d may be, for example, a hole at least partially surrounded by the first partition 377c and the first substrate 371, and may provide a path for the second light RL2 to enter the interior of the guide structure 307c. In one or more embodiments, the second guide hole 377d may provide a larger cross-sectional area than the first guide hole 373g or a larger space than the first guide hole 373g.

According to one or more embodiments, the second partition 377a may be at least partially disposed between the second accommodation space 307b and the guide structure 307c. For example, the second partition 377a may allow the first light RL1 reflected by the subject to be incident on the first detection area 375a, but may suppress or block it from being incident on the second detection area 375b. In one or more embodiments, the second partition 377a may suppress or block the second light RL2 guided to the second detection area 375b through the guide structure 307c from being incident on the first detection area 375a. In one or more embodiments, the second partition 377a may have a closed curve trajectory corresponding to the edge of the first detection area 375a. For example, the second partition 377a may be provided as a structure that divides or separates the space in which the first detection area 375a is arranged from the remaining space within the first casing 377.

According to one or more embodiments, the optical module 307 may include a lens assembly 379 configured to focus or guide the first light RL1 to the first detection area 375a. The lens assembly 379 may include, for example, at least one lens, and may guide the first light RL1 reflected by the subject to the first detection area 375a. For example, the diffractive optical element 373f or the collimator 373e may be an optical system that focuses or guides light emitted from the light-emitting element assembly 373 (e.g., emitted light EL) to be directed toward a subject, and the lens assembly 379 may be an optical system that guides light reflected by the subject (e.g., first light RL1) to the first detection area 375a.

According to one or more embodiments, the light-emitting element 373d, the diffractive optical element 373f, the collimator 373e, the lens assembly 379, and/or the light-receiving element 375 (e.g., the first detection area 375a) may be arranged or aligned to emit light (e.g., infrared laser light) toward the subject and receive light reflected by the subject after being emitted toward the subject. In one or more embodiments, the light-receiving element 375 may include a first detection area 375a configured to receive first light RL1 that is emitted by the light-emitting element assembly 373 and then reflected by the subject. In one or more embodiments, the light-receiving element 375 may include a second detection area 375b configured to receive second light RL2 (e.g., the second light RL2 in FIG. 13) that is a portion of the light emitted by the light-emitting element 373d and guided through a path within the optical module 307.

According to one or more embodiments, the light-emitting element 373d, the diffractive optical element 373f, the collimator, the lens assembly 379, and/or the light-receiving element 375 (e.g., the first detection area 375a) may be assembled to the first substrate 371 within a predetermined error range. In one or more embodiments, when the light-emitting element 373d, the diffractive optical element 373f, the collimator 373e, the lens assembly 379, and/or the light-receiving element 375 are individually assembled to the first substrate 371, if a defect occurs, a considerable amount of time may be required in the process of correcting the alignment status or error of the individual components, or the individual components may be damaged in the process of removing/replacing the individual components. In one or more embodiments, during the process of manufacturing/assembling the light-emitting element 373d, the diffractive optical element, and/or the collimator into the light-emitting element assembly 373, defects or errors in the light-emitting element assembly 373 may be identified/corrected, thereby facilitating improvement of the defect rate. In one or more embodiments, when the light-emitting element assembly 373 is already placed on the first substrate 371, any defects or errors identified during the process of assembling the light-receiving element 375 and/or the lens assembly 379 may be corrected during the process of assembling the light-receiving element 375 and/or the lens assembly 379, thereby reducing the time and cost required for manufacturing/assembling the optical module 307 and facilitating improvement in the defect rate.

According to one or more embodiments, the optical module 307 may include at least one reflective member (e.g., reflective member 473 in FIG. 11 or 12) and/or an inclined surface 377f. For example, in providing a portion of the light output from the light-emitting element 373d to the second detection area 375b, the optical module 307 may use the at least one reflective member 473 and/or the inclined surface 377f to guide the second light RL2 from the interior of the first accommodation space 307a (or the interior of the second casing 373c) to the guide structure 307c and/or to the second detection area 375b. In one or more embodiments, when light is reflected by a structure such as an inner wall of the second casing 373c or the collimator 373e, the optical module 307 may guide the reflected light to the guide structure 307c and/or to the second detection area 375b by using the at least one reflective member 473 and/or the inclined surface 377f. For example, by providing a portion of the output light as the second light RL2 by using the at least one reflective member 473 and/or the inclined surface 377f, light loss due to reflection, refraction, and/or scattering inside the optical module 307 may be suppressed. In one or more embodiments, by including the at least one reflective member 473 and/or the inclined surface 377f, the optical module 307 may have improved power efficiency and/or improved optical efficiency.

In one or more embodiments, the inclined surface 377f may be provided as at least a portion of the inner surface of the first casing 377 on the guide structure 307c. In one or more embodiments, the inclined surface 377f may be subjected to a reflective surface treatment (e.g., plating, printing, or coating) to guide the second light RL2 along a predetermined path. In one or more embodiments, the at least one reflective member 473 includes a reflective surface provided on the inclined surface 377f. In one or more embodiments, the inclined surface 377f may be provided between the second detection area 375b and the first partition 377c (e.g., the second guide hole 377d). In one or more embodiments, the inclined surface 377f may refer to an inclined surface (e.g., an inner surface of the first casing 377) relative to the first substrate 371 on the guide structure 307c. In one or more embodiments, the distance from the first substrate 371 to the inclined surface 377f at a position adjacent to the second guide hole 377d may be greater than the distance from the first substrate 371 to the inclined surface 377f at a position adjacent to the second detection area 375b. In one or more embodiments, the inclined surface 377f may be arranged so as not to substantially interfere with the second light RL2 in the path along which the second light RL2 travels from the first guide hole 373g to the second detection area 375b.

In one or more embodiments, at least one reflective member 473 may be provided on at least a portion of a structure facing the light-emitting element 373d (e.g., the inner surface of the second casing 373c or the collimator 373e), the integrated circuit chip 373b, the second substrate 373a, the first partition 377c, and/or the inner surface of the guide structure 307c. For example, the at least one reflective member 473 may be understood as a component that configures the propagation path of the second light RL2 from the light-emitting element 373d to the second detection area 375b. The arrangement of the at least one reflective member 473 will be described again with reference to FIGS. 11 to 13.

FIG. 9 is a perspective view illustrating the light-emitting element assembly 373 of the optical module 307 according to one or more embodiments. FIG. 10 is a perspective view illustrating the state in which the light-emitting element assembly 373 (e.g., the second casing 373c) of the optical module 307 is arranged in the first casing 377, according to one or more embodiments.

FIGS. 9 and 10 may exemplify the state in which the light-emitting element assembly 373 (e.g., the second casing 373c) is arranged in the first casing 377 in the state in which, for example, the first guide hole 373g is aligned with the guide structure 307c. Referring to FIGS. 9 and 10, the interior of the first casing 377 may include the first accommodation space 307a configured to accommodate the light-emitting element assembly 373 (e.g., the second casing 373c may be provided in the first accommodation space 307a), the second accommodation space 307b configured to accommodate a portion of the light-receiving element 375 (e.g., at least a portion of the first detection area 375a in FIG. 7), and/or the guide structure 307c disposed between the first accommodation space 307a and the second accommodation space 307b. In one or more embodiments, another portion of the light-receiving element 375, for example, at least a portion of the second detection area 375b, may be disposed in the guide structure 307c.

According to one or more embodiments, the first partition 377c may be disposed between the first accommodation space 307a and the guide structure 307c, and may provide the second guide hole 377d connecting the guide structure 307c to the first accommodation space 307a. When the first casing 377 is disposed on the first substrate 371 of FIG. 7, the second guide hole 377d may be at least partially surrounded by the first substrate 371 and the first partition 377c. In one or more embodiments, the second partition 377a may be disposed between the guide structure 307c and the second accommodation space 307b. In one or more embodiments, the second partition 377a may have a shape arranged to form a closed curve trajectory. For example, the second partition 377a may be provided in a closed curve shape or a polygonal ring shape corresponding to the edge of the first detection area 375a. For example, when the shape is arranged to form a closed curve trajectory, a portion of the second partition 377a is disposed in the guide structure 307c and the second accommodation space 307b, and the second accommodation space 307b is at least partially disposed between two different portions of the second partition 377a.

According to one or more embodiments, as described above, the light output by the light-emitting element 373d from the interior of the second casing 373c is substantially emitted toward the subject, but a portion of the output light (e.g., the second light RL2) may be reflected or refracted by an internal structure (e.g., an optical element such as the collimator 373e or the inner wall of the second casing 373c) and provided to the second detection area 375b. In one or more embodiments, when the second casing 373c is disposed in the first accommodation space 307a, the first guide hole 373g may be aligned with the guide structure 307c. For example, the light-emitting element assembly 373 may be disposed in the first accommodation space 307a at a position where the first guide hole 373g and the second guide hole 377d are aligned to face each other.

According to one or more embodiments, the relative positions of the light-emitting element 373d and the light-receiving element 375 (e.g., the second detection area 375b) may be determined differently depending on the specifications of the optical module 307. In order to ensure the amount of light of the second light RL2 reaching the second detection area 375b from the light-emitting element assembly 373, the sizes of the first guide hole 373g and the second guide hole 377d may be determined. In one or more embodiments, when the second guide hole 377d is implemented to be sufficiently larger than the first guide hole 373g, the degree of design freedom in the position or size of the first guide hole 373g may be increased. For example, considering the relative positions of the light-emitting element 373d and the light-receiving element 375 (e.g., the second detection area 375b), and/or the amount of light of the second light RL2 received in the second detection area 375b, the design of the size of the first guide hole 373g or the position of the first guide hole 373g in a direction D1 may be facilitated. In one or more embodiments, the power of light reaching the second detection area 375b may be increased in a structure in which the first guide hole 373g is disposed closer to the light-receiving element 375 (e.g., the second detection area 375b) compared to a state in which the first guide hole 373g is disposed closer to the central portion of the light-emitting element 373d. For example, the size or position of the first guide hole 373g may be determined considering the amount of light of the second light RL2 received in the second detection area 375b.

FIG. 11 is a plan view illustrating a portion of the light-emitting element assembly 373 of the optical module 307 according to one or more embodiments. FIG. 12 is a view illustrating the light-emitting element assembly 373 of the optical module 307 according to one or more embodiments. FIG. 13 is a view illustrating a path along which a reference light of an optical module 307 proceeds (e.g., the second light RL2) according to one or more embodiments.

Referring to FIGS. 11 to 13, light output from the light-emitting element 373d is generally emitted toward a subject, and a portion of the light output from the light-emitting element 373d (e.g., the second light RL2) may be reflected or refracted inside the optical module 307 and/or the light-emitting element assembly 373 and provided to the second detection area 375b via a guide structure 307c. The time at which the second light RL2 is detected in the second detection area 375b may be used as a basis for determining subject distance information, together with, for example, the time at which the first light RL1 is detected in the first detection area 375a by being reflected by the subject. In one or more embodiments, depending on the operating environment (e.g., temperature), there may be a deviation in the distance information for a subject at the same distance. For example, distance information based only on the time at which the first light RL1 is detected includes a deviation depending on the operating environment, and the time at which the second light RL2 is detected may be used to compensate for this deviation. Compensation for deviations according to these operating environments will be described again with reference to FIGS. 14 and 15.

According to one or more embodiments, the optical module 307 may include at least one reflective member 473 to guide or direct light reflected or refracted inside the optical module 307 to the second detection area 375b. For example, the at least one reflective member 473 may increase the amount or power of light reaching the first guide hole 373g and/or the second detection area 375b (e.g., the second light RL2) compared to a structure in which the reflective member is not disposed. The at least one reflective member 473 may be disposed on, for example, the integrated circuit chip 373b or the second substrate 373a, but may be sufficiently insulated so as not to affect electrical operation. In one or more embodiments, the at least one reflective member 473 may be provided on at least a portion of the collimator 373e, the inner wall of the second casing 373c, and/or the inner wall of the second guide hole 377d. The at least one reflective member 473 may include a plating layer, a printing layer, and/or a coating layer provided on the inner surface (e.g., the inclined surface 377f) of the first casing 377 on the guide structure 307c. For example, a structure may be implemented to guide or direct light that is not emitted toward a subject to the second detection area 375b by providing the at least one reflective member 473 inside the optical module 307.

According to one or more embodiments, when the light-emitting element 373d is a vertical cavity surface-emitting laser including a plurality of channels, the amount of light reaching the second detection area 375b may vary depending on the relative position of each channel. In one or more embodiments, considering the ratio of light reaching the second detection area 375b from the light emitted from each channel, the size and position of the first guide hole 373g, the size and position of the second guide hole 377d, and/or the size and position of the at least one reflective member 473 may be selected. For example, by using the size and position of the first guide hole 373g, the size and position of the second guide hole 377d, and/or the size and position of the at least one reflective member 473, the deviation of distance information according to the operating environment may be further suppressed. As the accuracy of distance information increases, the quality of subject images or the accuracy in user authentication may be increased.

FIG. 14 is a graph illustrating a first measurement result of the optical module 307 according to one or more embodiments. FIG. 15 is a graph illustrating a second measurement result of the optical module 307 according to one or more embodiments of the disclosure.

FIGS. 14 and 15 are graphs showing the measurements from the emission of light toward a subject at the same distance to the reception of the light reflected by the subject. The horizontal axis represents the time at which the light was emitted and/or the time at which the light was received by the light-receiving element 375, while the vertical axis represents the amount of light received. “TL” illustrated on the vertical axis may represent a threshold value for determining that the amount of light received is valid. For example, the optical module 307, the electronic device (e.g., the electronic device 1001, 1002, 1004, 100, or 200 in FIGS. 1 to 5), and/or at least one processor (e.g., the processor 1020 in FIG. 1) may utilize the time at which the light amount is received as the basis for determining distance information when the amount of light greater than or equal to “TL” is received. In one or more embodiments, a light source (e.g., the light-emitting element assembly 373) may emit a plurality of pulses (e.g., approximately 60,000 pulses), and distance information may be determined based on the time at which the number of pulses reflected by the subject and received by the light-receiving element 375 is the largest among the emitted pulses.

FIG. 14 illustrates a first reference time TR1 at which a portion of light (e.g., the second light RL2 in FIG. 13) emitted from the light-emitting element assembly 373 is received in the second detection area 375b when detecting distance information of a subject at a predetermined position for, for example, the optical module 307 or the electronic device (e.g., the electronic device 1001, 1002, 1004, 100, or 200 in FIGS. 1 to 5), and a first detection time TD1 at which the first light RL1 emitted from the light-emitting element assembly 373 and then reflected by the subject is received in the first detection area 375a. In one or more embodiments, the distance measurement of FIG. 14 may be understood as being performed at room temperature. The subject distance at a predetermined position at room temperature may be substantially determined based on the time taken from the first reference time TR1 to the first detection time TD1. For example, the subject distance information may be determined based on the first detection time TD1 without considering the first reference time TR1, but the optical module 307, the electronic device 200, and/or at least one processor 1020 according to the embodiment(s) of the disclosure may determine the subject distance information considering both the first reference time TR1 and the first detection time TD1.

FIG. 15 illustrates a second reference time TR2 at which a portion of light (e.g., the second light RL2 in FIG. 13) emitted from the light-emitting element assembly 373 is received in the second detection area 375b, and a second detection time point TD2 at which the first light RL1 emitted from the light-emitting element assembly 373 and then reflected by the subject is received in the first detection area 375a, for example, in detecting the distance information of the subject at substantially the same distance as the measurement in FIG. 14. In one or more embodiments, the distance measurement of FIG. 15 may be understood to have been performed in a state where the light-emitting element assembly 373 is raised to a temperature higher than room temperature (by about 10 degrees C.) by repeated photographing and/or repeated distance measurement. In the state of high temperature (e.g., the state of temperature raised by about 10 degrees C. from room temperature), the distance to the subject may be determined based on the time taken from the second reference time TR2 to the second detection time TD2. For example, the subject distance information may be determined based on the second detection time TD2 without considering the second reference time TR2, but in this case, even if light that has traveled the same distance is received, the time may be different from the time at which the light is received at room temperature due to a difference in the operating environment (e.g., temperature). The deviation in time due to these operating environments corresponds to reception deviation TC. For example, when the light-emitting element assembly 373 operates at a temperature that is about 10 degrees C. higher than room temperature, there may be a deviation equal to the difference between the first reference time TR1 and the second reference time TR2. The optical module 307, the electronic device (e.g., the electronic device 1001, 1002, 1004, 100, or 200 in FIGS. 1 to 5), and/or at least one processor (e.g., the processor 1020 of FIG. 1) according to one or more embodiments may suppress the deviation in distance measurement according to the operating environment by determining the subject distance considering the second reference time TR2 and the second detection time TD2 together.

In one or more embodiments, the distance to the subject may be determined based on the difference between the first reference time TR1 and the first detection time TD1 in FIG. 14. For example, the time value according to the difference between the first reference time TR1 and the first detection time TD1 and the speed of the light emitted from the light-emitting element assembly 373 may be variables used for determining the distance to the subject. In one or more embodiments, the distance to the subject may be determined based on the difference between the second reference time TR2 and the second detection time TD2 in FIG. 15. For example, since the deviation due to temperature change may occur substantially equally at the second reference time TR2 and the second detection time TD2 compared to the times TD1 and TR1 in FIG. 14, the time variable for determining the distance to the subject may be determined by directly comparing the second reference time TR2 and the second detection time TD2. In one or more embodiments, a reception deviation TC according to an operation environment may be stored in memory as data in a table form, and when measuring a subject distance, the reception deviation TC is compared with information stored in the memory and determined based on a detected reference time (e.g., the first reference time point TR1 in FIG. 14 or the second reference time point TR2 in FIG. 15), and the time variable for determining the distance to the subject may be determined or decided based on the difference between the detection time (e.g., the first detection time TD1 in FIG. 14 or the second detection time TD2 in FIG. 15) and the reception deviation TC. A method of measuring (or determining) a reception deviation TC and/or distance information to a subject is further described with reference to FIGS. 16 and 17.

FIG. 16 is a flowchart illustrating a method of measuring a reception deviation in an optical module (e.g., the optical module 307 in FIGS. 6 to 8) according to one or more embodiments. FIG. 17 is a flowchart illustrating a method of measuring subject distance information using an optical module (e.g., the optical module 307 in FIGS. 6 to 8) according to one or more embodiments.

According to one or more embodiments, after a reception deviation TC according to temperature is measured in advance by the measuring method 500 of FIG. 16, the measured information may be stored in memory (e.g., a memory 1030 of FIG. 1). At the time at which a distance is to be measured, a reception deviation TC corresponding to the time at which light is received in the second detection area 375b may be identified based on data stored in the memory by the measuring method 600 of FIG. 17.

Referring to FIG. 16, the reception deviation TC measuring method 500 may include an operation 501 of measuring a reception deviation TC and an operation 502 of storing the measured reception deviation TC. The operation 501 of measuring the reception deviation TC may be, for example, an operation of measuring time at which light emitted from the light-emitting element assembly 373 passes through the interior of an optical module 307 and reaches the second detection area 375b. The operation 502 of storing the measured reception deviation TC may be, for example, an operation of storing data in the form of a table matching a current measurement temperature and a corresponding reference time in the memory. For example, the reception deviation TC measuring method 500 may determine a reference time measured at a predetermined temperature (e.g., room temperature of about 20 degrees C.) as a first reference time TR1, repeatedly measure the reference time (e.g., the second reference time TR2 in FIG. 15) while changing the temperature of the surrounding environment, and/or store the reception deviation TC according to the temperature at the time of measurement (e.g., the time difference between the first reference time TR1 and the second reference time TR2) in the form of tabulated data in memory, whereby the reception deviation TC measuring method 500 may be performed or completed.

Referring to FIG. 17, a subject distance information measuring method 600 may include an operation 601 of measuring a distance, an operation 602 of compensating for a deviation, an operation 603 of determining a distance, and/or an operation 604 of obtaining an image. In one or more embodiments, when the electronic device 100 or 200 of FIGS. 2 to 5 acquires a subject image, the distance information determined by the subject distance information measuring method 600 may be used for processing or post-processing of the acquired image.

According to one or more embodiments, in operation 601, the electronic device 100 or 200 and/or the optical module 307 may emit light using the light-emitting element assembly 373. In one or more embodiments, a portion of the light emitted from the light-emitting element assembly 373 may be reflected by the subject and reach the first detection area 375a, and another portion of the light emitted from the light-emitting element assembly 373 may travel through the interior of the optical module 307 and reach the second detection area 375b. In one or more embodiments, even if the distance from the electronic device 100 or 200 and/or the optical module 307 to the subject is the same, a deviation may occur in the distance measurement value depending on the temperature at the time of measuring the distance information.

According to one or more embodiments, in operation 602, the electronic device 100 or 200 and/or the optical module 307 may determine a reception deviation TC corresponding to the time at which light reaches the second detection area 375b (e.g., the second reference time TR2) or based on the amount of light, and exclude the reception deviation TC determined at the time at which light reaches the first detection area 375a (e.g., the second detection time TD2), thereby compensating for the deviation of the measurement value due to the temperature difference. In one or more embodiments, operation 603 may be an operation of determining a measurement value compensated for the deviation as the distance to the subject. As described above, when the distance measuring method 600 of FIG. 17 is performed while capturing an image of the subject, the determined distance (e.g., the distance to the subject) may be used to improve the quality of the acquired image. For example, the distance measuring method 600 of FIG. 17 may be performed while capturing an image of the subject, and the distance information to the subject measured (or determined) in operation 603 may be used as one of the information items that form the basis of the image obtained in operation 604.

FIG. 18 is a perspective view illustrating the internal configuration of a wearable electronic device 700 according to one or more embodiments.

According to one or more embodiments of the disclosure, the wearable electronic device 700 of FIG. 18 (or the wearable electronic device 800 in FIGS. 19 and 20 described below) may be substantially identical to the electronic device 1001 of FIG. 1 and may be implemented to be wearable on a user's body. In one or more embodiments, each of the external electronic devices 1002 and 1004 of FIG. 1 may be of the same type as or different type from the electronic device 1001 or the wearable electronic devices 700 and 800. According to one or more embodiments, all or some of the operations executed in the electronic device 1001 or the wearable electronic devices 700 and 800 may be executed in one or more external electronic devices 1002, 1004, or 1008. For example, when the electronic device 1001 or the wearable electronic device 700 or 800 is to perform certain functions or services automatically or in response to a request from a user or other device, the electronic device 1001 or the wearable electronic device 700 or 800 may request that one or more external electronic devices execute at least some of the functions or the services, in place of or in addition to executing the functions or the services by itself. The one or more external electronic devices, which have received the above-mentioned request, may execute at least a portion of the requested functions or services, or additional functions or services associated with the request, and may transmit the result of the execution to the electronic device 1001 or the wearable electronic device 700 or 800. The electronic device 1001 or the wearable electronic device 700 or 800 may provide the result as part of a response to the request as it is, or may further process the result and provide the processed result at least part of a response to the request. For example, the external electronic device 1002 renders content data executed by the application and then delivers the rendered content data to the electronic device 1001 or the wearable electronic device 700 or 800, and the electronic device 100 or the wearable electronic device 700 or 800, which receives the data, may output the content data to a display module (e.g., the display module 1060, the light output module 711, or the second display 821 in FIG. 1). When the electronic device 1001 or the wearable electronic device 700 or 800 detects the movement of the user via an inertial measurement unit sensor or the like, the processor (e.g., the processor 1020 in FIG. 1) of the electronic device 1001 or the wearable electronic device 700 or 800 may correct, based on the motion information, the rendered data received from the external electronic device 1002 and may output the corrected data to the display module. Alternatively, the motion information may be delivered to the external electronic device 1002 and rendering may be requested such that the screen data is updated accordingly. According to one or more embodiments, the external electronic device 1002 may be of various types, such as a case device that is capable of storing and charging the electronic device 1001.

Referring to FIG. 18, the wearable electronic device 700 according to one or more embodiments may include at least one of a light output module 711, a display member 701, and a camera module 750. According to one or more embodiments, the light output module 711 may include a light source capable of outputting an image (e.g., the projector or the display panel 911a in FIG. 21), and a lens (e.g., the lens 911b in FIG. 21) that guides the image to the display member 701. According to one or more embodiments, the light output module 711 may include at least one of a liquid crystal display (LCD), a digital mirror device (DMD), a liquid crystal-on-silicon (LCOS) display device, an organic light-emitting diode (OLED), or a micro LED (a micro-LED).

According to one or more embodiments, the display member 701 may include a light waveguide (e.g., the light waveguide 913a in FIG. 21). According to one or more embodiments, the output image of the light output modules 711 incident on one ends of the light waveguides may be propagated within the light waveguides and provided to the user. For example, the display member 701 may be an optical system that guides or focuses an image output from the light output module 711 along a predetermined path (e.g., the first path P1 in FIG. 21) to a user's eyes.

According to one or more embodiments, the display member 701 may include at least one of a DOE, a holographic optical element (HOE), or a reflective element (e.g., a reflective mirror) provided in the light waveguide (e.g., the couplers 913b and 913c in FIG. 21). For example, the display member 701 may include at least one diffractive optical element, a holographic optical element, or a reflective element, and/or may include a light waveguide to guide the output image of the light output module 711 to a user's eyes.

According to one or more embodiments, the camera module 750 may capture a still image and/or a video image. According to one or more embodiments, the camera module 750 may be disposed in the lens frame and around the display member 701. In one or more embodiments, by including the optical module 307 of FIGS. 6 to 8, the wearable electronic device 700 may obtain information about the distance to the subject when capturing a still image and/or a video image using the camera module 750.

According to one or more embodiments, the first camera module 751 may capture and/or recognize the trajectory of the user's eye (e.g., pupil or iris) or gaze. According to one or more embodiments of the disclosure, the first camera module 751 may periodically or aperiodically transmit information related to the trajectory of the user's eye or gaze (e.g., trajectory information) to the processor (e.g., the processor 1020 in FIG. 1).

According to one or more embodiments, the second camera module 753 may capture an external image.

According to one or more embodiments, the third camera module 755 may be used for hand detection and tracking, as well as use gesture (e.g., hand movement) recognition. According to one or more embodiments, the third camera module 755 may be used for 3 degrees of freedom (3 DoF) or 6 DoF head tracking, position (space, environment) recognition, and/or movement recognition. According to one or more embodiments, the second camera module 753 may also be used for hand detection and tracking, as well as user gesture recognition. According to one or more embodiments, at least one of the first to third camera modules 751, 753 and 755 may be replaced with a sensor module (e.g., LiDAR sensor). For example, the sensor module may include at least one of a VCSEL, an infrared sensor, and/or a photodiode. In one or more embodiments, the sensor module may be implemented by the optical module 307 of FIGS. 6 to 8.

According to one or more embodiments, the wearable electronic device 700 may include a pair of display members 701 arranged side by side. For example, a user may wear the wearable electronic device 700 on his face, and the display members 701 may be arranged to correspond to the user's eyes, respectively, while the wearable electronic device 700 is worn on the user's face. In one or more embodiments, when including a pair of display members 701, the wearable electronic device 700 may provide visual information to the user through any one of the display members 701 and/or through each display member 701.

According to one or more embodiments, the wearable electronic device 700 may include one or more wearing member 702a and 702b extending from or rotatably coupled to the display members 701. In one or more embodiments, the wearing members 702a and 702b may be exemplified as a structure rotatably coupled (or connected) to the display members 701 by hinge structures H, respectively. For example, the wearing members 702a and 702b may be in a position overlapped or folded with the wearing members 701, thereby making in convenient for the user to carry or store the wearable electronic device 700. In one or more embodiments, the wearable electronic device 700 may be easily worn on the face by the user at a position where the wearing members 702a and 702b are rotated by a predetermined angle (e.g., about 90 degrees) from the position where the display members 701 overlap the user's face. For example, the wearable electronic device 700 may be stably worn by supporting the display members 701 on the user's face and supporting the wearing members 702a and 702b on the side surfaces of the user's head (e.g., on the ears).

FIGS. 19 and 20 are views illustrating the front and rear sides of a wearable electronic device 800 according to one or more embodiments.

Referring to FIGS. 19 and 20, in one or more embodiments, camera modules 811, 812, 813, 814, 815, and 816 and/or a depth sensor 817 configured to acquire information related to the environments surrounding the wearable electronic device 300 may be disposed on a first surface 810 of a housing.

In one or more embodiments, the camera modules 811 and 812 may acquire images related to the surrounding environment of the wearable electronic device 800.

In one or more embodiments, the camera modules 813, 814, 815, and 816 may acquire images while the wearable electronic device 800 is worn by the user. In one or more embodiments, by including the optical module 307 of FIGS. 6 to 8, the wearable electronic device 800 may obtain information about the distance to a subject when obtaining images using the camera modules 813, 814, 815, and 816. The camera modules 813, 814, 815, and 816 may be used for hand detection and tracking, or user gesture (e.g., hand gesture) recognition. The camera modules 813, 814, 815, and 816 may be used for 3 DoF or 6 DoF head tracking, position (space, environment) recognition, and/or movement recognition. In one or more embodiments, the camera modules 811 and 812 may be used for hand detection and tracking, as well as user gesture recognition.

In one or more embodiments, the depth sensor 817 may be configured to transmit a signal and receive a signal reflected from a subject, and may be used to identify the distance to an object, such as time of flight (TOF). Instead of or in addition to the depth sensor 817, the camera modules 813, 814, 815, and 816 may identify the distance to an object. In one or more embodiments, the depth sensor 817 may be implemented by the optical module 307 of FIGS. 6 to 8.

According to one or more embodiments, face recognition camera modules 825 and 826 and/or displays 821 (and/or lenses) may be disposed on a second surface 820 of the housing.

In one or more embodiments, the face recognition camera modules 825 and 826 adjacent to the displays 821 may be used to recognize a user's face, or may recognize and/or track a user's both eyes.

In one or more embodiments, the displays 821 (and/or lenses) may be disposed on the second surface 820 of the wearable electronic device 800. In one or more embodiments, the wearable electronic device 800 may not include the camera module(s) indicated as “815” and/or “816” among the plurality of camera modules 813, 814, 815, and 816. The wearable electronic device 800 may further include at least one of the components illustrated in FIG. 18.

As described above, according to one or more embodiments, the wearable electronic device 800 may have a form factor to be worn on a user's head. The wearable electronic device 800 may further include a strap for being secured on a user's body part, and/or a wearing member (e.g., the wearing members 702a and 702b in FIG. 18). The wearable electronic device 800 may provide a user experience based on augmented reality, virtual reality, and/or mixed reality while worn on the user's head.

FIG. 21 is a diagram illustrating a portion of a wearable electronic device (e.g., the electronic device 1001 of FIG. 1 and/or the wearable electronic device 700 or 800 in FIGS. 18 to 20) according to one or more embodiments.

Referring to FIG. 21, the wearable electronic device may include a light output module 911 (e.g., the light output module 711 in FIG. 18), a display member 901 (e.g., the display member 701 in FIG. 18), a first polarizing reflector 961, a polarizing modulator 963, and/or a second polarizing reflector 965. The display member 901 may be, for example, a see-through optical element (see-through optics) that transmits light or an image about an environment or an object O around a user and provides the user with the light or image along a predetermined path (e.g., a second path P2). In one or more embodiments, the display element 901 may be a transmissive optical element and may provide a first path P1 that guides or directs light (e.g., visual information such as text or images) output from the light output module 911 to the user's eye E. For example, by including a transmissive optical element (e.g., the display member 901), the wearable electronic device may provide an environment in which a user is capable of visually recognizing a surrounding space or an object O, and may visually provide stored information or received information to the user using the light output module 911 and the display member 901.

According to one or more embodiments, when visually providing various information to the user, a portion of the light output by the light output module 911 may leak into the external space. In one or more embodiments, the first polarizing reflector 961, the polarizing modulator 963, and/or the second polarizing reflector 965 may reflect at least a portion of the light leaking into the external space to provide it to the user, and/or may absorb a portion of the light leaking into the external space. In one or more embodiments, when the first polarizing reflector 961, the polarizing modulator 963, and/or the second polarizing reflector 965 reflects light leaking into the external space, the wearable electronic device may provide visual information to the user more clearly or more brightly. For example, the wearable electronic device may have improved light efficiency or improved power efficiency.

According to one or more embodiments, the light output module 911 may include a display panel 911a that outputs light (e.g., visual information such as an image) and at least one lens 911b. The display panel 911a may include, for example, the above-described liquid crystal display, a digital mirror display device, a silicon liquid crystal display device, an organic light-emitting diode, or a micro LED. In one or more embodiments, the lens 911b may guide or focus light output from the display panel 911a to the display member 901. In one or more embodiments, the light output module 911 may further include a reflective member (e.g., a mirror) or a refractive member (e.g., a prism) to guide or align light to the display member 901. For example, depending on the direction in which the display panel 911a is aligned, the light output module 911 may further include a reflective member or a refractive member to output light in a direction toward the display member 901.

According to one or more embodiments, the display member 901 may include a first surface F1 and a second surface F2 opposite to the first surface F1. In one or more embodiments, when the wearable electronic device is worn on the user's face, the first surface F1 may be substantially arranged to face the user's face or the naked eye, and the second surface F2 may be arranged to face an external space (e.g., the environment around the user). In one or more embodiments, an image of the surrounding environment or an object O may be provided to the user by being incident on the second surface F2 along the second path P2 and output through the first surface F1. For example, the display member 901 can transmit at least a portion of the light incident on the second surface F2 to the first surface F1. In one or more embodiments, the light output from the light output module 911 may be provided to the user by traveling through the interior of the display member 901 along the first path P1 and being output through the first surface F1. For example, the display member 901 may guide light output from the light output module 911 to the user's eye.

According to one or more embodiments, by including a light waveguide 913a and the couplers 913b and 913c, the display member 901 may provide light output from the light output module 911 to the user. Of the couplers 913b and 913c, a first coupler 913b may be provided at one end of the light waveguide 913a and aligned with the light output module 911. For example, the light guided or focused by the lens 911b may be input into the light waveguide 913a through the first coupler 913b. Of the couplers 913b and 913c, a second coupler 913c may be provided at the other end of the light waveguide 913a. In one or more embodiments, when the wearable electronic device is worn on the user's face, the second coupler 913c may be substantially aligned with the user's naked eye. For example, the light guided or focused by the lens 911b may be input into the light waveguide 913a through the first coupler 913b and may travel along the light waveguide 913a, and the light traveling along the light waveguide 913a may be provided to the user's eye by the second coupler 913c.

According to one or more embodiments, the first coupler 913b and/or the second coupler 913c may include at least one of a DOE, a HOE, and/or a reflective element. For example, the light output from the light output module 911 may be input into the light waveguide 913a by the first coupler 913b, and the light traveling along the light waveguide 913a may be output to the first surface F1 by the second coupler 913c. At the time at which the direction of light propagation is controlled by the first coupler 913b and/or the second coupler 913c, and/or at the time at which the light propagating through the light waveguide 913a is reflected within the light waveguide 913a, a portion of the light may leak out to the outside. By including the first polarizing reflector 961, the polarizing modulator 963, and/or the second polarizing reflector 965, the wearable electronic device according to the embodiment(s) of the disclosure may suppress light output from the light output module 911 from leaking out to the outside.

In one or more embodiments, the first polarizing reflector 961, the polarizing modulator 963, and/or the second polarizing reflector 965 are exemplified as being arranged at positions corresponding to the second coupler 913c. However, when there is a portion in which light output from the light output module 911 may leak out in the path along which the light travels through the display member 901, the first polarizing reflector 961, the polarizing modulator 963, and/or the second polarizing reflector 965 may be further extended or additionally arranged at an appropriate position. For example, the first polarizing reflector 961, the polarizing modulator 963, and/or the second polarizing reflector 965 may be extended or additionally disposed to a position corresponding to the first coupler 913b or the light waveguide 913a. In one or more embodiments, the first polarizing reflector 961, the polarizing modulator 963, and/or the second polarizing reflector 965 may be disposed substantially over the entire area of the second surface F2. In one or more embodiments, when the structure sufficiently suppresses the leakage of light traveling along the first path P1, the first polarizing reflector 961, the polarizing modulator 963, and/or the second polarizing reflector 965 may be omitted in the wearable electronic device.

According to one or more embodiments, the first polarizing reflector 961 is arranged on one surface (e.g., the second surface F2) of the display member 901 and may be configured to reflect or absorb at least a portion of light that leaks outward via the second coupler 913c. For example, when visual information to be provided to the user is provided to the user, a portion of the light output from the light output module 911 may be output to the second surface F2 via the second coupler 913c. The first polarizing reflector 961 may enhance the light efficiency of the wearable electronic device by reflecting the light output to the second surface F2 via the second coupler 913c to the first surface F1.

According to one or more embodiments, when the first polarizing reflector 961 is configured to reflect light of a first polarization component (e.g., horizontal linear polarization (p-pol)), light of a second polarization component different from the first polarization component (e.g., vertical linear polarization (s-pol)) may be transmitted through the first polarizing reflector 961. In one or more embodiments, similar to the first polarizing reflector 961, the second polarizing reflector 965 may be configured to reflect light of the first polarization component, and the polarizing modulator 963 may modulate at least a portion of the light transmitted through the first polarizing reflector 961 into light of the first polarization component and transmit it to the second polarizing reflector 965. For simplicity of explanation, in one or more embodiments, the light of the first polarization component may be referred to as horizontal linear polarization, and the light of the second polarization component may be referred to as vertical linear polarization. However, it should be noted that the embodiment of the disclosure are not limited thereto. In one or more embodiments, when light of a third polarization component, such as circular polarization or elliptically polarized light, is incident on the first polarizing reflector 961 (or the second polarizing reflector 965), a portion of the light of the third polarization component may transmit through the first polarizing reflector 961 (or the second polarizing reflector 965), and at least a portion of the remaining light of the third polarization component may be reflected by the first polarizing reflector 961 (or the second polarizing reflector 965).

According to one or more embodiments, the polarizing modulator 963 may be disposed on the first polarizing reflector 961. For example, the polarizing modulator 963 may be disposed to substantially face the second surface F2 with the first polarizing reflector 961 interposed therebetween. In one or more embodiments, the polarizing modulator 963 may be disposed between the first polarizing reflector 961 and the second polarizing reflector 965 to modulate at least a portion of the polarization component of the light transmitted through the first polarizing reflector 961. For example, the polarizing modulator 963 may modulate at least a portion of the light transmitted through the first polarizing reflector 961 into light having a polarization component which is reflected by the second polarizing reflector 965. In one or more embodiments, the polarizing modulator 963 may substantially transmit light transmitted through the first polarizing reflector 961, but may modulate at least a portion of the polarization component of the light transmitted through the polarizing modulator 963. In one or more embodiments, the polarizing modulator 963 may include a wave plate 963a (e.g., a half-wave wave plate) and a rotator 963b (e.g., a Faraday rotator). In one or more embodiments, the wave plate 963a may change the polarization direction of light passing through the polarizing modulator 963 by a predetermined angle, and the rotator 963b may modulate the polarization axis of light passing through the polarizing modulator 963 in a predetermined direction. Depending on the specifications of the wearable electronic device 700 or 800 or the display member 901, the optical elements (e.g., the wave plate 963a and/or the rotator 963b) included in the polarizing modulator 963 may be implemented differently from the exemplified ones.

According to one or more embodiments, the second polarizing reflector 965 may be disposed on the polarizing modulator 963. For example, the second polarizing reflector 965 may be disposed to substantially face the second surface F2 with the first polarizing reflector 961 and the polarizing modulator 963 interposed therebetween. In one or more embodiments, the second polarizing reflector 965 may reflect at least a portion of the light transmitted through the polarizing modulator 963 and guide it to the second surface F2 and/or the first surface F1. For example, the second polarizing reflector 965 may reflect light of the first polarization component, and at least a portion of the light transmitted through the polarizing modulator 963 may be light of the first polarization component.

According to one or more embodiments, when including the optical module 307 of FIGS. 6 to 8, the wearable electronic device 700 or 800 may detect (or determine) information about the distance to a subject when acquiring an image of the subject. For example, by including subject distance information in processing images provided to the user, the wearable electronic device 700 or 800 may provide images of improved quality to the user.

As described above, an optical module (e.g., the optical module 307 in FIGS. 6 to 8) and/or an electronic device including the same (e.g., the electronic device 1001, 1002, 1004, 100, or 200 in FIGS. 1 to 5) according to one or more embodiments is provided with a structure in which a light-emitting element assembly (e.g., the light-emitting element assembly 373 in FIG. 7) including a light-emitting element (e.g., the light-emitting element 373d in FIG. 7) and/or a driving circuit thereof (e.g., the integrated circuit chip 373b in FIG. 7) is placed on a substrate (e.g., the first substrate 371 in FIG. 7) on which a light-receiving element (e.g., the light-receiving element 375 of FIG. 7) is placed through a surface mount technique, thereby suppressing damage to components that may occur during a manufacturing process or in the correction of defects. In one or more embodiments, the substrate of the light-emitting element assembly (e.g., the second substrate 373a) on which the light-emitting element and/or the driving circuit thereof of FIG. 7 is placed) and/or the substrate of the optical module on which such substrate is arranged (e.g., the first substrate 371 on which the light-emitting element assembly and/or the light-receiving element of FIG. 7 is placed) may include a ceramic material such as LTCC or HTCC, thereby rapidly dispersing or releasing heat generated during the operation of the light-emitting element. For example, the operating environment of the light-emitting element or the electronic device may be suppressed from deteriorating due to heat generation. In one or more embodiments, the optical module may guide or direct light reflected or refracted inside to the light-receiving element (e.g., the second detection area 375b in FIG. 7) to be used for distance measurement. For example, the optical efficiency and/or power efficiency of the optical module may be improved, and the accuracy of distance measurement may be enhanced. In one or more embodiments, by appropriately designing (or manufacturing) the shape or the size of the internal space of the light-emitting element assembly or the first casing 377, the amount of light (e.g., the second light RL2) guided to the first guide hole 373g or the second detection area 375b may be sufficiently ensured. When the amount of light (e.g., the second light RL2) guided to the first guide hole 373g or the second detection area 375b is sufficiently ensured, the deviation in the subject distance measurement caused by the change in the operating environment (e.g., temperature) may be suppressed.

Advantageous effects obtainable from the disclosure may not be limited to the above-mentioned effects, and other effects which are not mentioned may be clearly understood, through the following descriptions, by those skilled in the art to which the disclosure pertains.

According to one or more embodiments, an optical module (e.g., the optical module 307 in FIGS. 6 to 8) may include a first substrate (e.g., the first substrate 371 in FIG. 7), a light-emitting element assembly (e.g., the light-emitting element assembly 373 in FIG. 7) disposed on the first substrate and configured to emit light in a predetermined wavelength band, a light-receiving element (e.g., the light-receiving element 375 in FIG. 7) disposed on the first substrate on one side of the light-emitting device assembly and including a first detection area (e.g., the first detection area 375a in FIG. 7) configured to receive first light (e.g., the first element RL1 in FIG. 6) emitted by the light-emitting device assembly and then reflected by a subject, and a first casing (e.g., the first casing 377 in FIG. 7) disposed on the first substrate and including a second accommodation space (e.g., the second accommodation space 307b in FIG. 7) configured to accommodate the first detection area, a guide structure (e.g., the guide structure 307c in FIG. 7) disposed between a first accommodation space (e.g., the first accommodation space 307a of FIG. 7) and the second accommodation space, and a second partition (e.g., the second partition 377a in FIG. 7) extending from an inner surface between the guide structure and the second accommodation space and facing the light-receiving element. In one or more embodiments, the light-receiving element may further include a second detection area (e.g., the second detection area 375b in FIG. 7) provided on one side of the first detection area and disposed at least partially inside the guide structure. In one or more embodiments, the second detection area is configured to receive second light (e.g., the second light RL2 in FIG. 13) guided by the guiding structure, the second light being a portion of light emitted by the light-emitting element assembly.

According to one or more embodiments, the light-emitting device assembly may include a second substrate (e.g., the second substrate 373a in FIG. 7) including a ceramic material, a driving circuit (e.g., the integrated circuit chip 373b in FIG. 7) mounted on the second substrate, and a light-emitting element (e.g., the light-emitting element 373d in FIG. 7) controlled by the driving circuit and configured to emit light in the predetermined wavelength band.

According to one or more embodiments, the light-emitting device assembly may include a second casing (e.g., the second casing 373c in FIG. 7) disposed on the second substrate to accommodate at least the light-emitting element, and a first guide hole (e.g., the first guide hole 373g in FIG. 7) provided in the second casing and aligned with the guide structure within the first casing. In one or more embodiments, the first guide hole is configured to guide the second light into the interior of the guide structure.

According to one or more embodiments, the optical module may further include at least one reflective member (e.g., the reflective member 473 in FIG. 11 or 12) disposed in an interior space of the second casing or the interior of the guide structure.

According to one or more embodiments, the optical module may further include a first partition (e.g., the first partition 377c in FIG. 7) disposed inside the first casing between the guide structure and the light-emitting element assembly, and a second guide hole (e.g., the second guide hole 377d in FIG. 7) at least partially surrounded by the first partition and the first substrate. In one or more embodiments, the first guide hole may be aligned with the second guide hole.

According to one or more embodiments, the light-emitting device assembly may include a DOE (e.g., the DOE 373f in FIG. 7), and a collimator (e.g., the collimator 373e in FIG. 7). In one or more embodiments, the DOE and the collimator may be configured to guide or align at least a portion of the light emitted from the light-emitting element in a predetermined direction.

According to one or more embodiments, the light-emitting element may include a VCSEL.

According to one or more embodiments, the optical module may further include a lens assembly (e.g., the lens assembly 379 in FIG. 7) disposed on the first casing and configured to guide or focus the first light to the first detection area.

According to one or more embodiments, the first casing is configured to further provide a first accommodation space (e.g., the first accommodation space 307a in FIG. 7) configured to accommodate the light-emitting element assembly. In one or more embodiments, the guide structure may be disposed between the first accommodation space and the second accommodation space.

According to one or more embodiments, the second partition may be configured to suppress or block the first light from being incident on the second detection area.

According to one or more embodiments, the second partition may be configured to suppress or block the second light from being incident on the first detection area.

According to one or more embodiments, the second partition may be arranged to form a closed curve trajectory corresponding to an edge of the first detection area.

According to one or more embodiments, at least a portion of an inner surface (e.g., the inclined surface 377f in FIG. 7) of the first casing on the guide structure may be inclined with respect to the first substrate.

According to one or more embodiments, an electronic device (e.g., the electronic device 1001, 1002, 1004, 100, or 200 in FIGS. 1 to 5) may include a housing (e.g., the housing 201 in FIG. 4 or 5), an optical module (e.g., the optical module 307 in FIGS. 6 to 8) arranged in the housing and configured to emit light of a predetermined wavelength band and receive first light (e.g., the first light RL1 in FIG. 6) reflected by a subject from the emitted light, at least one processor (e.g., the processor 1020 in FIG. 1), and memory (e.g., the memory 1030 in FIG. 1) configured to store instructions that cause the electronic device to determine distance information to the subject based on at least the first light when individually or collectively executed by the at least one processor. In one or more embodiments, the optical module may include a first substrate (e.g., the first substrate 371 in FIG. 7), a light-emitting element assembly (e.g., the light-emitting element assembly 373 in FIG. 7) disposed on the first substrate and configured to emit light in a predetermined wavelength band, a light-receiving element (e.g., the light-receiving element 375 in FIG. 7) disposed on the first substrate at one side of the light-emitting element assembly and including a first detection area (e.g., the first detection area 375a in FIG. 7) configured to receive the first light, and a first casing (e.g., the first casing 377 in FIG. 7) disposed on the first substrate and including a first accommodation space (e.g., the first accommodation space 307a in FIG. 7) configured to accommodate the light-emitting element assembly, a second accommodation space (e.g., the second accommodation space 307b in FIG. 7) configured to accommodate the first detection area, and a guide structure (e.g., the guide structure 307c in FIG. 7) arranged between the first accommodation space and the second accommodation space. In one or more embodiments, the light-receiving element may further include a second detection area (e.g., the second detection area 375b in FIG. 7) provided on one side of the first detection area and disposed at least partially inside the guide structure. In one or more embodiments, the second detection area is configured to receive second light (e.g., the second light RL2 in FIG. 13) guided by the guiding structure, the second light being a portion of light emitted by the light-emitting element assembly.

According to one or more embodiments, the light-emitting device assembly may include a second substrate (e.g., the second substrate 373a in FIG. 7) including a ceramic material, a driving circuit (e.g., the integrated circuit chip 373b in FIG. 7) mounted on the second substrate, a light-emitting element (e.g., the light-emitting element 373d in FIG. 7) controlled by the driving circuit and configured to emit light in the predetermined wavelength band, a second casing (e.g., the second casing 373c in FIG. 7) disposed on the second substrate to accommodate at least the light-emitting element, and a first guide hole (e.g., the first guide hole 373g in FIG. 7) provided in the second casing and aligned with the guide structure within the first casing. In one or more embodiments, the first guide hole may be configured to guide the second light into the interior of the guide structure.

According to one or more embodiments, the light-emitting element assembly may further include at least one reflective member (e.g., the reflective member 473 in FIG. 11 or 12) disposed in an interior space of the second casing or the interior of the guide structure.

According to one or more embodiments, the light-emitting element assembly may further include a DOE (e.g., the DOE 373f in FIG. 7), and a collimator (e.g., the collimator 373e in FIG. 7). In one or more embodiments, the diffractive optical element and the collimator may be configured to guide or align at least a portion of the light emitted from the light-emitting element in a predetermined direction.

According to one or more embodiments, the light-emitting element may include a vertical cavity surface emitting laser.

According to one or more embodiments, the light-emitting element assembly further includes a second partition (e.g., the second partition 377a in FIG. 7) extending from the inner surface of the first casing between the guide structure and the second accommodation space and arranged to face the light-receiving element.

According to one or more embodiments, the second partition may be configured to suppress or block the first light from being incident on the second detection area, and to suppress or block the second light from being incident on the first detection area.

By utilizing information about the distance to a subject (or the depth of a subject), the quality of captured images or videos may be improved even in a miniaturized electronic device. This distance information may be used to implement security functions such as user facial recognition. Distance information may be detected, for example, by emitting light (e.g., infrared) from the electronic device, receiving the light reflected by a subject, and measuring the time from the time of emission to the time of reception. For example, the electronic device may detect the distance information to the subject by including an infrared light source and an infrared receiver. Infrared laser light may be usefully utilized for measuring the distance information to the subject. High temperature heat may be generated when radiating infrared laser light, and when the operating environment changes due to the generated heat, distance information for a subject at the same distance may be detected differently.

Embodiments of the disclosure are intended to at least resolve the above-described problems and/or disadvantages and at least provide the advantages described above, and may provide an optical module and/or an electronic device including the same, which is easily disperse or release the generated heat.

Although the disclosure has been described with reference to embodiments as an example, it is to be understood that the embodiments are intended to be exemplary and is not limiting the disclosure. It will be apparent to those skilled in the art that various changes in form and detail may be made without departing from the overall scope of the disclosure, including the appended claims and their equivalents. For example, in describing a reception deviation according to an operating environment, the difference in the operating environment is exemplified as a temperature of about 10 degrees C., but it should be noted that the embodiments of the disclosure are not limited thereto. In one or more embodiments, the deviation of the operating environment may differ from those mentioned in the above-described embodiments, depending on the duration and cycle of photographing (or distance measurement), or the operating mode of the optical module (or the electronic device) and the temperature of the space in which the operating module (or the electronic device) is currently located.

According to one or more embodiments, an optical module may include a light-emitting element assembly including a light-emitting element configured to emit first light, a light-receiving element adjacent to the light-emitting element assembly, the light-receiving element including a first detection area and a second detection area adjacent to the first detection area, a first casing accommodating the first detection area and the second detection area, the first casing including a first guide hole, and a second casing accommodating the light-emitting element and including a second guide hole aligned with the first guide hole, wherein the first detection area is configured to receive second light that is emitted by the light-emitting element and then reflected by a subject, and wherein the second detection area is configured to receive third light through the first guide hole and the second guide hole, the third light being a portion of the first light.

According to one or more embodiments, wherein the light-emitting element assembly may be configured to generate the third light by reflecting or refracting the portion of the first light through the second guide hole.

According to one or more embodiments, wherein the light-emitting element assembly may further include a collimator and at least one reflector, the collimator and the at least one reflector being configured to reflect or refract the portion of the first light through the second guide hole.

According to one or more embodiments, wherein the first casing may further include a first accommodation space accommodating the light-emitting element assembly, a second accommodation space accommodating the first detection area, a guide structure between the first accommodation space and the second accommodation space, the guide structure accommodating the second detection area, a first partition between the first accommodation space and the guide structure, and a second partition between the guide structure and the second accommodation space.

According to one or more embodiments, wherein the first guide hole may be in the first partition, and wherein the second partition may be configured to block the second light from being incident on the second detection area.

The embodiments of the disclosure disclosed in the specification and the drawings provide merely specific examples to easily describe technical content according to the embodiments of the disclosure and help the understanding of the embodiments of the disclosure, not intended to limit the scope of the embodiments of the disclosure. Accordingly, the scope of various embodiments of the disclosure should be interpreted as encompassing all modifications or variations derived based on the technical spirit of various embodiments of the disclosure in addition to the embodiments disclosed herein.

What is claimed is:

1. An optical module comprising:
a first substrate;
a light-emitting element assembly on the first substrate, the light-emitting element being configured to emit light in a predetermined wavelength band;
a light-receiving element on the first substrate and adjacent to one side of the light-emitting element assembly, the light-receiving element comprising a first detection area configured to receive first light that is emitted by the light-emitting element assembly and then reflected by a subject; and
a first casing on the first substrate, the first casing comprising:
a first accommodation space,
a second accommodation space accommodating the first detection area,
a guide structure between the first accommodation space and the second accommodation space, and
a partition extending from an inner surface between the guide structure and the second accommodation space and facing the light-receiving element,
wherein the light-receiving element further comprises a second detection area adjacent to one side of the first detection area and at least partially inside the guide structure, and
wherein the second detection area is configured to receive second light that is a portion of the light that is emitted by the light-emitting element assembly and guided by the guide structure.

2. The optical module of claim 1, wherein the light-emitting element assembly comprises:
a second substrate comprising a ceramic material;
a driving circuit on the second substrate; and
a light-emitting element controlled by the driving circuit and configured to emit the light in the predetermined wavelength band.

3. The optical module of claim 2, wherein the light-emitting element assembly further comprises:
a second casing on the second substrate and accommodating at least the light-emitting element; and
a first guide hole on the second casing and aligned with the guide structure of the first casing, and
wherein the first guide hole is configured to guide the second light into an interior of the guide structure.

4. The optical module of claim 3, further comprising at least one reflective member in an interior space of the second casing or the interior of the guide structure.

5. The optical module of claim 3, further comprising:
another partition inside the first casing and between the guide structure and the light-emitting element assembly; and
a second guide hole at least partially surrounded by the other partition and the first substrate,
wherein the first guide hole is aligned with the second guide hole.

6. The optical module of claim 2, wherein the light-emitting element assembly further comprises:
a diffractive optical element; and
a collimator, and
wherein the diffractive optical element and the collimator are configured to guide or align at least a portion of the light emitted from the light-emitting element in a predetermined direction.

7. The optical module of claim 2, wherein the light-emitting element comprises a vertical cavity surface emitting laser.

8. The optical module of claim 1, further comprising:
a lens assembly on the first casing and configured to guide or focus the first light to the first detection area.

9. The optical module of claim 1, wherein the light-emitting element assembly is accommodated in the first accommodation space.

10. The optical module of claim 1, wherein the partition is configured to suppress or block the first light from being incident on the second detection area.

11. The optical module of claim 1, wherein the partition is configured to suppress or block the second light from being incident on the first detection area.

12. The optical module of claim 1, wherein the partition is arranged to form a closed curve trajectory corresponding to an edge of the first detection area.

13. The optical module of claim 1, wherein at least a portion of an inner surface of the guide structure is inclined with respect to the first substrate.

14. An electronic device comprising:
a housing;
an optical module in the housing, the optical module being configured to emit light of a predetermined wavelength band and receive first light reflected by a subject;
at least one processor; and
memory configured to store instructions that, when executed by the at least one processor, cause the electronic device to determine distance information to the subject based on at least the first light,
wherein the optical module comprises:
a first substrate;
a light-emitting element assembly on the first substrate and configured to emit the light of the predetermined wavelength band;
a light-receiving element on the first substrate and adjacent to one side of the light-emitting element assembly, the light-receiving element comprising a first detection area configured to receive the first light; and
a first casing on the first substrate, the first casing comprising:
a first accommodation space accommodating the light-emitting element assembly;
a second accommodation space accommodating the first detection area; and
a guide structure between the first accommodation space and the second accommodation space,
wherein the light-receiving element further comprises a second detection area adjacent to one side of the first detection area and at least partially inside the guide structure, and
wherein the second detection area is configured to receive second light that is a portion of the light emitted by the light-emitting element assembly and guided by the guide structure.

15. The electronic device of claim 14, wherein the light-emitting element assembly further comprises:
a second substrate comprising a ceramic material;
a driving circuit on the second substrate;
a light-emitting element controlled by the driving circuit and configured to emit the light in the predetermined wavelength band;
a second casing on the second substrate and accommodating at least the light-emitting element; and
a first guide hole on the second casing and aligned with the guide structure, and
wherein the first guide hole is configured to guide the second light into an interior of the guide structure.

16. The electronic device of claim 15, wherein the light-emitting element assembly further comprises at least one reflective member in an interior space of the second casing or the interior of the guide structure.

17. The electronic device of claim 15, wherein the light-emitting element assembly further comprises:
a diffractive optical element; and
a collimator, and
wherein the diffractive optical element and the collimator are configured to guide or align at least a portion of the light emitted from the light-emitting element in a predetermined direction.

18. The electronic device of claim 15, wherein the light-emitting element comprises a vertical cavity surface emitting laser.

19. The electronic device of claim 14, wherein the light-emitting element assembly further comprises a partition extending from an inner surface of the first casing between the guide structure and the second accommodation space and arranged to face the light-receiving element.

20. The electronic device of claim 19, wherein the partition is configured to:
suppress or block the first light from being incident on the second detection area; and
suppress or block the second light from being incident on the first detection area.
